(19) United States
(12) Patent Application Publication
(10) Pub. No.: US 2013/0171757 A1
(43) Pub. Date: Jul. 4, 2013

(54) ADVANCED PLATFORM FOR PASSIVATING CRYSTALLINE SILICON SOLAR CELLS

(71) Applicants: HARI K. PONNEKANTI, San Jose, CA (US); Alexander S. Polyak, San Jose, CA (US); James L'Heureux, Santa Clara, CA (US); Michael S. Cox, Gilroy, CA (US); Christopher T. Lane, Los Gatos, CA (US); Edward P. Hammond, IV, Hillsborough, CA (US); Hemant P. Mungekar, Campbell, CA (US); Susanne Schlaefer, Aschaffenburg (DE); Wolfgang Buschbeck, Hanau (DE); Juergen Henrich, Limeshain (DE); Andreas Lopp, Freigericht-Somborn (DE)

(72) Inventors: HARI K. PONNEKANTI, San Jose, CA (US); Alexander S. Polyak, San Jose, CA (US); James L'Heureux, Santa Clara, CA (US); Michael S. Cox, Gilroy, CA (US); Christopher T. Lane, Los Gatos, CA (US); Edward P. Hammond, IV, Hillsborough, CA (US); Hemant P. Mungekar, Campbell, CA (US); Susanne Schlaefer, Aschaffenburg (DE); Wolfgang Buschbeck, Hanau (DE); Juergen Henrich, Limeshain (DE); Andreas Lopp, Freigericht-Somborn (DE)

(21) Appl. No.: 13/732,662

(22) Filed: Jan. 2, 2013

Related U.S. Application Data
(60) Provisional application No. 61/582,698, filed on Jan. 3, 2012.
(60) Provisional application No. 61/596,654, filed on Feb. 8, 2012.
(60) Provisional application No. 61/612,080, filed on Mar. 16, 2012.
(60) Provisional application No. 61/661,313, filed on Jun. 18, 2012.

(51) Int. Cl. H01L 31/18

(52) U.S. Cl. CPC H01L 31/18
USPC 438/57; 118/719

(57) ABSTRACT

The present invention generally provides a high throughput substrate processing system that is used to form one or more regions of a solar cell device. In one configuration of a processing system, one or more solar cell passivating or dielectric layers are deposited and further processed within one or more processing chambers contained within the high throughput substrate processing system. The processing chambers may be, for example, plasma enhanced chemical vapor deposition (PECVD) chambers, low pressure chemical vapor deposition (LPCVD) chambers, atomic layer deposition (ALD) chambers, physical vapor deposition (PVD) or sputtering chambers, thermal processing chambers (e.g., RTA or RTO chambers), substrate reorientation chambers (e.g., flipping chambers) and/or other similar processing chambers.

### CROSS-REFERENCE TO RELATED APPLICATIONS

This application claims benefit of U.S. provisional patent application Ser. No. 61/582,698, filed Jan. 3, 2012, U.S. provisional patent application Ser. No. 61/596,654, filed Feb. 8, 2012, Unites States provisional patent application Ser. No. 61/612,080 filed Mar. 16, 2012, and U.S. provisional patent application Ser. No. 61/661,313, filed Jun. 18, 2012, each of which is incorporated herein by reference.

### BACKGROUND OF THE INVENTION

1. Field of the Invention

Embodiments of the invention generally relate to an apparatus and method of forming layers on a substrate used to form a solar cell device. The invention is particularly useful for fabrication of crystalline silicon solar cells.

2. Description of the Related Art

Photovoltaic (PV) or solar cells are devices which convert sunlight into direct current (DC) electrical power. A typical PV cell includes a p-type silicon wafer, or substrate, typically less than about 0.3 mm thick, with a thin layer of an n-type silicon material disposed on top of the p-type substrate. The generated voltage, or photo-voltage, and generated current by the PV cell are dependent on the material properties of the p-n junction, the interfacial properties between deposited layers, and the surface area of the device. When exposed to sunlight (consisting of energy from photons), the p-n junction of the PV cell generates pairs of free electrons and holes. An electric field formed across a depletion region of the p-n junction separates the free electrons and holes, creating a voltage. A circuit from n-side to p-side allows the flow of electrons when the PV cell is connected to an electrical load. Electrical power is the product of the voltage times the current generated as the electrons and holes move through the external electrical load and eventually recombine. Each solar cell generates a specific amount of electrical power. A plurality of solar cells is tiled into modules sized to deliver the desired amount of system power.

The PV market has experienced growth with annual growth rates exceeding above 30% for the last ten years. Some articles have suggested that solar cell power production world wide may exceed 10 GWp in the near future. It has been estimated that more than 90% of all photovoltaic modules are silicon wafer based. The high market growth rate in combination with the need to substantially reduce solar electricity costs has resulted in a number of serious challenges for silicon wafer production development for photovoltaics.

There are various approaches for fabricating the active regions and the current carrying metal lines, or conductors, of the formed solar cells. Manufacturing high efficiency solar cells at low cost is the key for making solar cells more competitive for the generation of electricity for mass consumption. The efficiency of solar cells is directly related to the ability of a cell to collect charges generated from absorbed photons in the various layers. Good front surface and rear surface passivation layers can help to reduce the recombination of the generated electrons or holes in the formed solar cell device, and redirect electrons and holes back into the solar cells to generate a desirable photocurrent. When electrons and holes recombine, the incident solar energy is re-emitted as heat or light, thereby lowering the conversion efficiency of the solar cells. Also, in general, a passivation layer will have desirable optical properties to minimize light reflection and absorption as light passes through the passivation layer, and desirable functional properties to “surface” passivate the surface(s) it is disposed over, “bulk” passivate the adjacent regions and surface of the substrate, and store a desired charge to “field” passivate the solar cell substrate surface that it is disposed over. The formation of a desirable passivation layer on a solar cell can greatly improve the efficiency of the solar cell, yet, the refractive index (n) and the inherent extinction coefficient (k) of the formed front side passivation layer(s) needs to be tuned with the surrounding layers to minimize light reflection and enhance light absorption by the solar cell device. However, deposition rate, and thus the ultimate number of substrates which can be processed in a set period of time, has an effect on the index of refraction and k values, as well as the physical properties of the film, such as the density.

In order to meet these challenges, the following solar cell processing requirements generally need to be met: 1) the cost of ownership (CoO) for substrate fabrication equipment needs to be improved (e.g., high system throughput, high machine up-time, inexpensive machines, inexpensive consumable costs), 2) the area processed per process cycle needs to be increased (e.g., reduce processing per Wp) and 3) the quality of the formed layers and film stack formation processes needs to be well controlled and sufficient to produce highly efficient solar cells. Therefore, there is a need to cost effectively form and manufacture silicon sheets for solar cell applications.

Further, as the demand for solar cell devices continues to grow, there is a trend to reduce cost by increasing the substrate throughput and improving the quality of the deposition processes performed on the substrate. However, the cost associated with producing and supporting all of the processing components in a solar cell production line continues to escalate dramatically. To reduce this cost while also reducing surface contamination, there is a need for a design of a novel solar cell processing system and processing sequence that has a high throughput, improved device yield, reduced number of substrate handling steps, and a compact system footprint.

### SUMMARY OF THE INVENTION

Aspects of the present invention generally provide a high throughput substrate processing system that is used to form one or more regions of a solar cell device. In one configuration of a processing system, one or more solar cell passivating or dielectric layers are deposited and further processed within one or more processing chambers contained within the high throughput substrate processing system. The processing chambers may be, for example, plasma enhanced chemical vapor deposition (PECVD) chambers, low pressure chemical vapor deposition (LPCVD) chambers, atomic layer deposition (ALD) chambers, physical vapor deposition (PVD) or sputtering chambers, thermal processing chambers (e.g., RTA or RTO chambers), substrate reorientation chambers (e.g., flipping chambers) and/or other similar processing chambers.

In one embodiment, a solar cell processing system, comprises a substrate automation system having one or more conveyors that are configured to transfer substrates serially through a processing region in a first direction, wherein the processing region is maintained at a pressure below atmospheric pressure, a first processing chamber having two or more first deposition sources disposed in the processing region, wherein each first deposition source is configured to separately deliver a processing gas to a surface of each of the substrates as the substrates are transferred through the processing region relative to the two or more first deposition sources, and a second processing chamber having two or more first deposition sources disposed in the processing region, wherein each second deposition source is configured to separately deliver a processing gas to the surface of each of the substrates as the substrates are transferred through the processing region relative to the two or more second deposition sources.

In another embodiment, a solar cell processing system, comprises a substrate automation system having two or more conveyors that are configured to transfer substrates through a processing region in a first direction, wherein the processing region is maintained at a pressure below atmospheric pressure, two or more first deposition sources that are each disposed in the processing region, and disposed in a spaced apart relationship along the first direction and a distance from a first portion of one of the two or more conveyors, wherein each first deposition source is configured to separately deliver a first processing gas to the first portion of the conveyor as the substrates are transferred through the processing region relative to the two or more first deposition sources, one or more first energy sources configured to deliver energy to a region formed between the first portion of the conveyor and one of the two or more first deposition sources, and two or more second deposition sources that are each disposed in the processing region, and disposed in a spaced apart relationship along the first direction and a distance from a second portion of one of the two or more conveyors, wherein each second deposition source is configured to separately deliver a second processing gas to the second portion of the conveyor as the substrates are transferred through the processing region relative to the two or more second deposition sources.

In yet another embodiment, a method of forming a solar cell, comprises reducing the pressure in a processing region of a solar cell processing system to a pressure below atmospheric pressure, positioning substrates on a substrate automation system that is at least partially disposed in the processing region, wherein the substrate automation system is configured to transfer substrates in a first direction through at least a portion of the processing region, delivering a first processing gas from two or more first deposition sources that are each disposed in the processing region, and disposed in a spaced apart relationship along the first direction and a distance from a first portion of the substrate automation system, wherein each of the two or more first deposition sources are configured to deliver the first processing gas to a deposition region formed between the first deposition source and at least one of the substrates positioned on the substrate automation system, and forming a plasma in the deposition region by delivering energy from a source.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a schematic isometric view of one embodiment of a substrate processing system.

FIG. 2A is a schematic cross-sectional plan view of an automated substrate processing system according to one embodiment described herein.

FIG. 2B is a schematic cross-sectional plan view of an automated substrate processing system according to one embodiment described herein.

FIG. 2C is a schematic side cross-sectional view of an automated substrate processing system according to one embodiment described herein.

FIG. 3 is a cross-sectional view of a solar cell substrate formed in the substrate processing system according to one embodiment described herein.

FIG. 4 is a schematic side cross-sectional view of a processing chamber according to one embodiment of the present invention.

FIG. 5A is a schematic side cross-sectional view of a deposition chamber according to one embodiment of the present invention.

FIG. 5B is a schematic side cross-sectional view of the deposition chamber illustrated in FIG. 5A according to an embodiment of the present invention.

FIG. 5C is a more detailed schematic side cross-sectional view of a region of the deposition chamber shown in FIG. 5A according to an embodiment of the present invention.

FIG. 5D is a schematic side cross-sectional view of a region of the deposition chamber shown in FIG. 5A according to one embodiment of the present invention.

FIG. 6 is a schematic side cross-sectional view of a deposition chamber according to one embodiment of the present invention.

FIG. 7A is a schematic isometric partial cross-sectional view of a reorientation chamber according to an embodiment of the present invention.

FIG. 7B is a schematic side cross-sectional view of a reorientation chamber according to an embodiment of the present invention.

FIG. 8A is a schematic plan view of a dynamic load lock chamber according to one embodiment of the present invention.

FIG. 8B is a schematic, cross-sectional view of the dynamic load lock chamber shown in FIG. 8A taken along section line B-B.

FIG. 8C is a partial plan view of a separation mechanism attached to a transport belt according to one embodiment.

FIG. 8D is a cross-sectional view of the separation mechanism of FIG. 8C taken along lines D-D.

FIG. 8E is a cross-sectional view of the separation mechanism of FIG. 8C taken along line E-E.

FIG. 8F is a schematic end view of the separation mechanism from FIG. 8C.

FIG. 9A is a schematic plan view of a substrate processing system according to an embodiment described herein.

FIG. 9B is a schematic plan view of a substrate processing system according to an embodiment described herein.

FIG. 9C is a schematic plan view of a substrate processing system according to an embodiment described herein.

FIG. 10 illustrates a processing sequence that may be performed in the automated substrate processing system according to an embodiment described herein.

For clarity, identical reference numerals have been used, where applicable, to designate identical elements that are common between figures. It is contemplated that features of one embodiment may be incorporated in other embodiments without further recitation.

### DETAILED DESCRIPTION

The present invention generally provides a high throughput substrate processing system, or cluster tool, for in-situ processing of a film stack used to form regions of a solar cell device. In one configuration, a film stack formed on each of the substrates contains one or more passivating or dielectric layers that are deposited and further processed within one or more processing chambers contained within the high throughput substrate processing system. The processing chambers may be, for example, plasma enhanced chemical vapor deposition (PECVD) chambers, low pressure chemical vapor deposition (LPCVD) chambers, atomic layer deposition (ALD) chambers, physical vapor deposition (PVD) chambers, thermal processing chambers (e.g., RTA or RTO chambers), substrate reorientation chambers (e.g., flipping chambers) and/or other similar processing chambers.

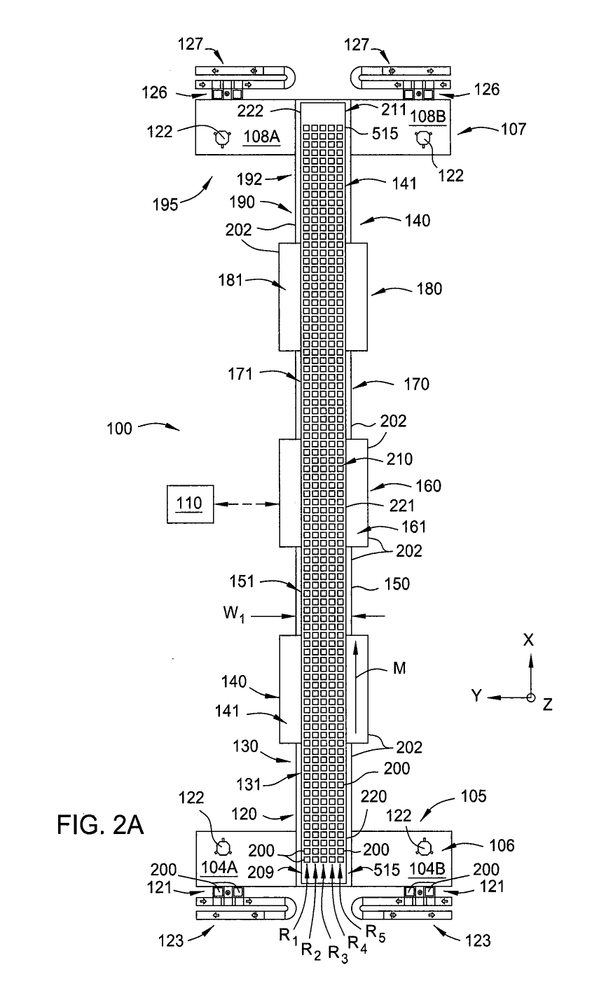

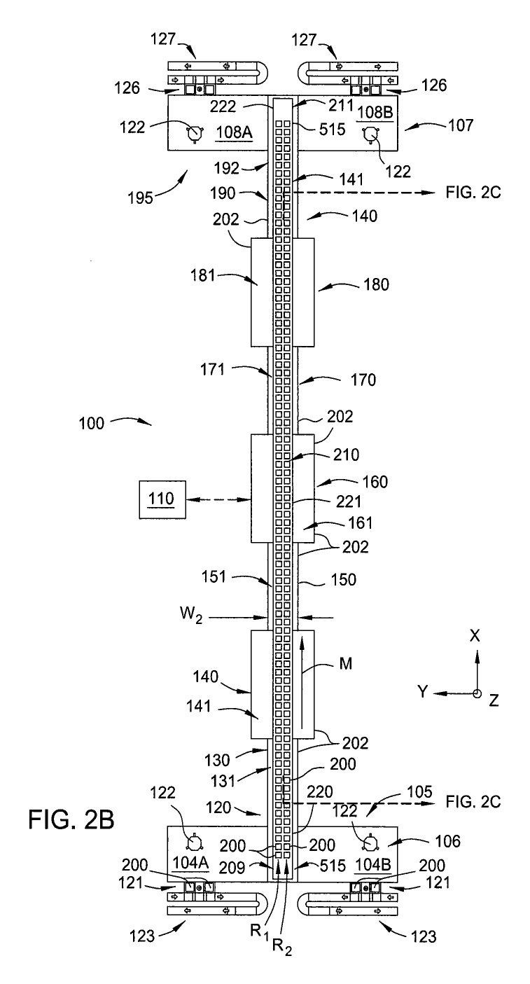

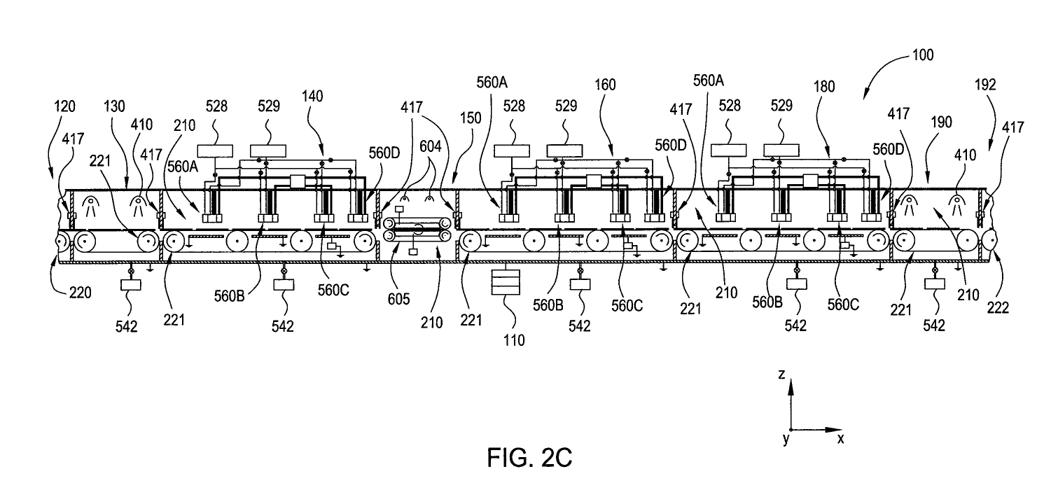

The high throughput substrate processing system may include one or more deposition chambers in which substrates are exposed to one or more gas-phase materials and an RF plasma. In one embodiment, the processing system includes at least one plasma enhanced chemical vapor deposition (PECVD) processing chamber that has been adapted to simultaneously process a plurality of substrates as they pass through the system in a linear direction. In one embodiment, solar cell substrates are simultaneously transferred in a vacuum or inert environment through the linear system to prevent substrate contamination and improve substrate throughput. In some embodiments, the substrates 200 are arranged in a linear array, such as shown in FIGS. 2A-2B, for processing as opposed to processing vertical stacks of substrates (e.g., batches of substrates stacked in cassettes) or planar arrays of substrates that are typically transferred on a substrate carrier in a batch. Such processing of substrates arranged in linear arrays allows each of the substrates to be directly and uniformly exposed to the generated plasma, radiant heat, and/or processing gases. The linear array may contain sub-sets or groups of the substrates that are similarly processed as they are serially transferred through the processing system. In this configuration, the sub-sets or groups of substrates are generally substrates disposed in the linear array that are similarly aligned in a direction perpendicular to the substrate transfer direction, and thus will be similarly processed at any given time during the processing sequence. Thus, processing groups of substrates that are disposed in linear arrays does not rely on diffusion type processes or the serial transfer of energy from one substrate to the next, such as undesirably found in conventionally configured vertical stack or back-to-back batch substrate processing.

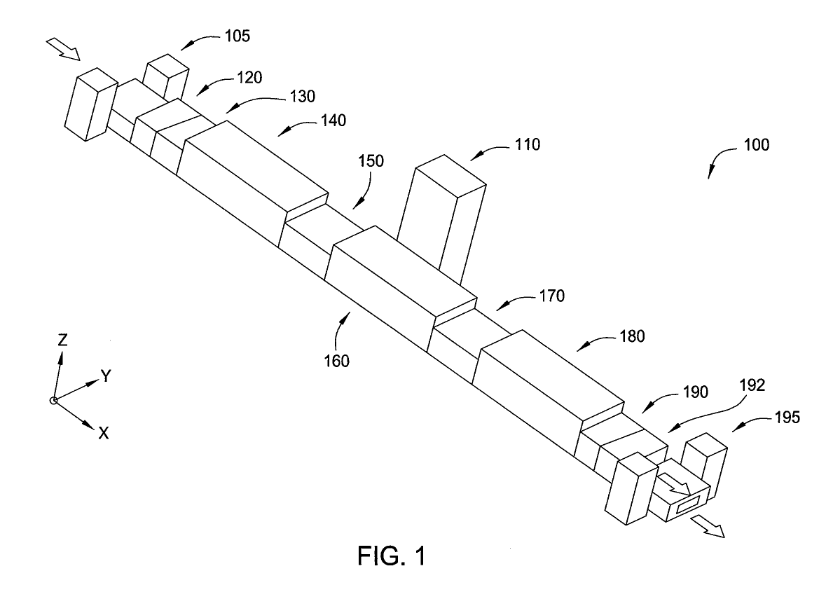

One skilled in the art will appreciate that conventional substrate processing systems that require the movement of batches of substrates in multiple directions as it is transferred through a processing system will require a structural element, such as a substrate carrier, to support and maintain the alignment and position of the substrates relative to each other during processing. The addition of substrate carriers within the processing system leads to a number of undesirable processing issues, increased system complexity and device yield issues. In one example, due to the addition of the mass of a substrate carrier in the processing region of a processing chamber during processing, the rapid heating or cooling of the substrates will be much harder to achieve because of the increased thermal mass and thermal inertia of the chamber due to the addition of substrate carrier. The addition of a substrate carrier also increases system complexity, due to the need to continually clean and return the substrate carrier after being processed in the system, so that it can receive the next batch of substrates. Also, the addition of substrate carriers creates a need for additional automation and robotic hardware to position the substrates in the substrate carrier prior to processing in the system and then remove the substrates from the substrate carrier after processing in the system. As solar cell substrates become thinner and thinner (e.g., <0.3 mm) the need to minimize the number of robotic pick-up, transfer and drop-off movements that are performed on the substrates has greatly increased. Therefore, in one embodiment of the invention, the processing system 100 (FIG. 1) is configured so that no “pick and place” type robotic transferring steps are performed during the movement of the substrate through the processing system. Pick and place type transferring processes generally include the steps of transferring substrates from one position to another in the processing system by use of a robot blade, vacuum chucking device, or other similar individual repositioning method that require repetitive interaction of an end-effector to enable the transfer of the substrate from one point in the system to the other. Also, typically “pick-and-place” type devices only minimally support the weight of the transferred substrate to reduce the number of particles created by the frequent interaction between the substrates and the end-effector that supports the substrates as they are transferred through the system.

Embodiments of the of the invention disclosed herein can be used to rapidly form the next generation solar cell devices in a high throughput substrate processing system, such as a processing system 100 that is illustrated in FIGS. 1-2B and 7A-7C and further discussed below. In some configurations, the next generation solar cell devices will contain multiple deposited layers, such as advanced passivation layers, that are formed on both sides of a solar cell substrate in the processing system 100. As noted above, forming layers, such as high quality passivation layers, on both sides of the substrate can reduce carrier recombination, redirect electrons and holes back into the solar cells to generate a desirable photocurrent, and act as a rear side reflector to better collect the incident solar energy. However, as one skilled in the art will appreciate, the ability of a processing system to form and process multiple layers on both sides of a substrate, while maintaining a high substrate throughput (e.g., >3000 substrates per hour) and provide a repeatable and desirable film quality has been elusive for the solar cell fabrication industry. The processing system configurations described herein are thus generally configured to reliably form a high quality advanced passivation layer on both surfaces of a solar cell substrate.

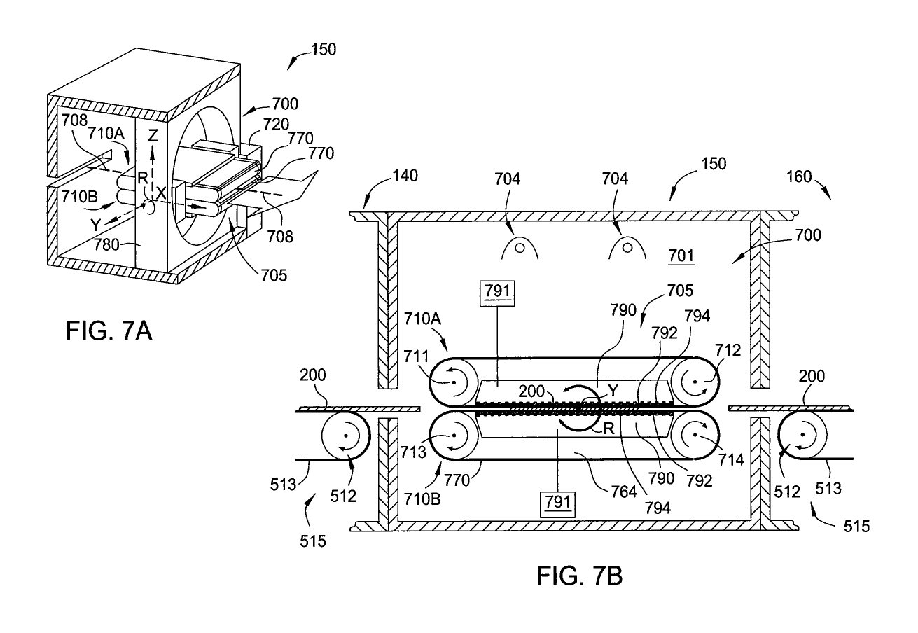

FIGS. 1 and 2A-2B illustrate a substrate processing system 100 for performing one or more solar cell fabrication processes on a linear array of substrates according to an embodiment of the present invention. In one embodiment, the substrate processing system 100 may include a substrate receiving chamber 105, a dynamic load lock chamber 120, pre-processing chamber 130, at least one processing chamber, such as a first processing chamber 140, a second processing chamber 160, and a third processing chamber 180, at least one transferring chamber, such as transferring chambers 150 and 170, a buffer chamber 190, a second dynamic load lock chamber 192 and a substrate unload chamber 195. FIGS. 7A-7C, which are further discussed below, each illustrate some alternate configurations of the processing system 100 according to some embodiments of the present invention. Collectively, the processing chambers 130-190 may include one of the following types of chambers PECVD chambers, LPCVD chambers, hot wire chemical vapor deposition (HWCVD) chambers, ion implant/doping chambers, plasma nitridation chambers, atomic layer deposition (ALD) chambers, physical vapor deposition (PVD) or sputtering chambers, plasma or vapor chemical etching chambers, thermal processing chambers (e.g., RTA or RTO chambers), substrate reorientation chambers (e.g., flipping chambers) and/or other similar processing chambers.

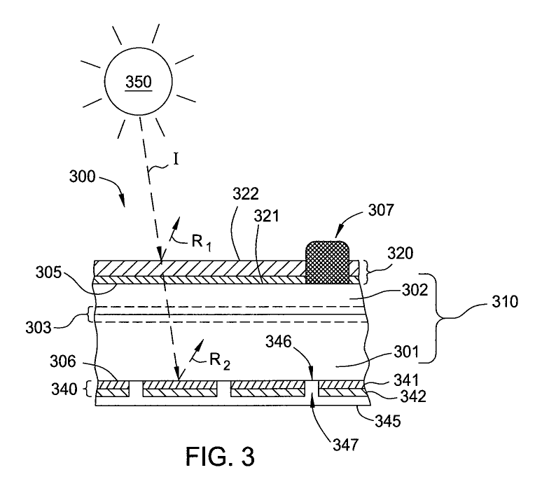

FIG. 3 illustrates a cross-sectional view of a solar cell substrate 310 that has a passivation/ARC layer stack 320 on a front surface (e.g., top surface 305) of a formed solar cell device 300, front side electrical contacts 307, a rear surface passivation layer stack 340 on a rear surface (e.g., rear surface 306) and a conductive layer 345 that forms rear side electrical contacts 346 that electrically contact the surface of the substrate 310 through via regions 347 formed in the passivation layer stack 340. In one embodiment, a substrate 310 comprises a silicon substrate that has a p-type dopant disposed therein to form part of the solar cell device 300. In this configuration, the substrate 310 may have a p-type doped base region 301 and an n-doped emitter region 302 formed thereon, typically by a doping and diffusion/anneal process, although other processes including ion implant may be used. The substrate 310 also includes a p-n junction region 303 that is disposed between base region 301 and emitter region 302 of the solar cell, and the substrate 310 is the region in which electron-hole pairs are generated when solar cell device 300 is illuminated by incident photons “I” of light from the sun 350. The conductive layer 345 and front side electrical contacts 307 may comprise a metal, such as the aluminum (Al), silver (Ag), tin (Sn), cobalt (Co), nickel (Ni), zinc (Zn), lead (Pb), tungsten (W), titanium (Ti), tantalum (Ta), nickel vanadium (NiV), or other similar materials, and combinations thereof.

In one example, the formed solar cell device 300 comprises a passivation/ARC layer stack 320 and a rear surface passivation layer stack 340 that each contain at least two or more layers of deposited material that are all formed on the substrate 310 in the processing system 100. The substrate 310, which is similar to substrate 200 discussed herein, may comprise single crystal silicon, multi-crystalline silicon, or polycrystalline silicon, but may also be useful for substrates comprising germanium (Ge), gallium arsenide (GaAs), cadmium telluride (CdTe), cadmium sulfide (CdS), copper indium gallium selenide (CIGS), copper indium selenide (CuInSe2), gallilium indium phosphide (GaInP2), organic materials, as well as heterojunction cells, such as GaInP/GaAs/Ge or ZnSe/GaAs/Ge substrates, that are used to convert sunlight to electrical power. The passivation/ARC layer stack 320 may comprise a first layer 321 that is in contact with the substrate surface 305 and a second layer 322 that is disposed on the first layer 321. In one example, the first layer 321 may comprise a silicon nitride (SiN) layer formed by a plasma enhanced chemical vapor deposition (PECVD) process that is between about 50 Angstroms (Å) and about 350 Å thick, such as 150 Å thick, and has a desirable quantity (Q₁) of trapped charge formed therein, to effectively passivate the substrate surface 305. In one example, the second layer 322 may comprise a silicon nitride (SiN) layer formed by a PECVD process that is between about 400 Å and about 700 Å thick, such as 600 Å thick, which may have a desirable quantity (Q₂) of trapped charge formed therein, to effectively help bulk passivate the substrate surface 305. One will note that the type of charge, such as a positive or negative net charge based on the sum of Q₁ and Q₂, is preferentially set by the type of substrate over which the passivation layers are formed. However, in one example, a total net positive charge of between about 5×10¹¹ Coulombs/cm² to about 1×10¹³ Coulombs/cm² is desirably achieved over an n-type substrate surface, whereas a total net negative charge of between about 5×10¹¹ Coulombs/cm² to about 1×10¹³ Coulombs/cm² would desirably be achieved over a p-type substrate surface. In this configuration of the solar cell device 300, the rear surface passivation layer stack 340 may comprise a first backside layer 341 that is in contact with the substrate rear surface 306 and a second backside layer 342 that is disposed on the first backside layer 341. In one example, the first backside layer 341 may comprise an aluminum oxide (AlₓO_{y}) layer formed by a formed by a PECVD process that is between about 200 Angstroms (Å) and about 1300 Å thick, and has a desirable quantity (Q₃) of trapped charge formed therein, to effectively passivate the substrate rear surface 306. In one example, the second backside layer 342 may comprise a silicon nitride (SiN) layer formed by a PECVD process that is between about 600 Å and about 2500 Å thick, which may have a desirable quantity (Q₄) of trapped charge formed therein, to effectively help passivate the substrate rear surface 306. One will note that the type of charge, such as a positive or negative net charge based on the sum of Q₃ and Q₄, is preferentially set by the type of substrate over which the passivation layers are formed, as discussed above. In one embodiment of the solar cell device 300 the selection of the passivation/ARC layer stack 320 and a rear surface passivation layer stack 340 will minimize the front surface reflection R₁ and maximize the rear surface reflection R₂ in the formed device, respectively, as shown in FIG. 3, to improve the efficiency of the solar cell device.

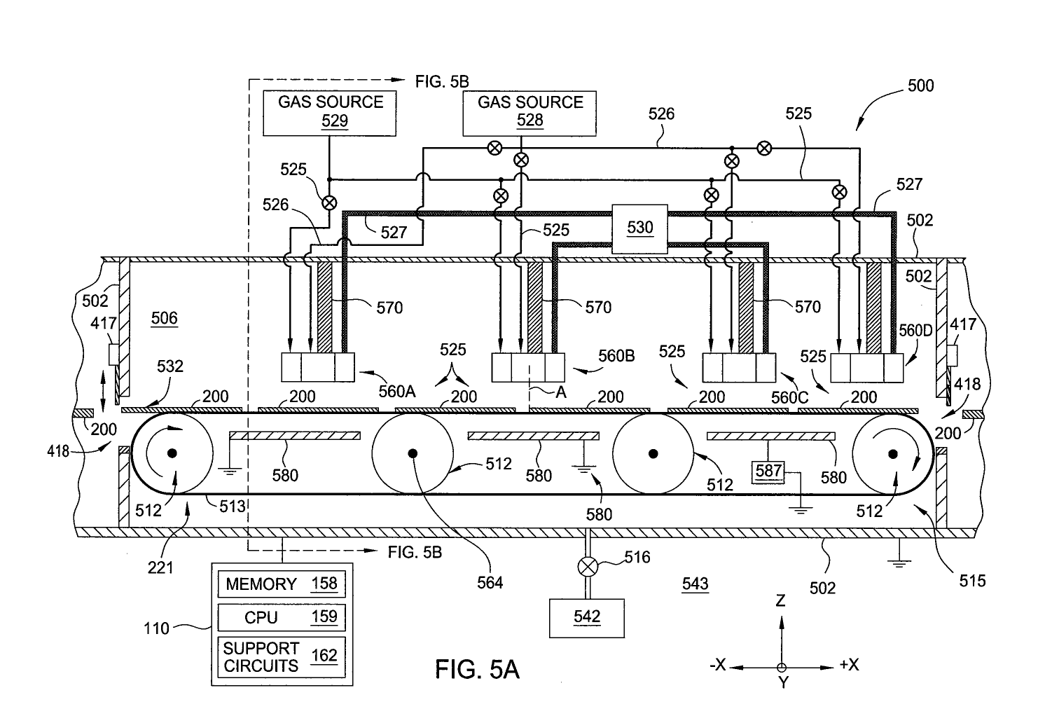

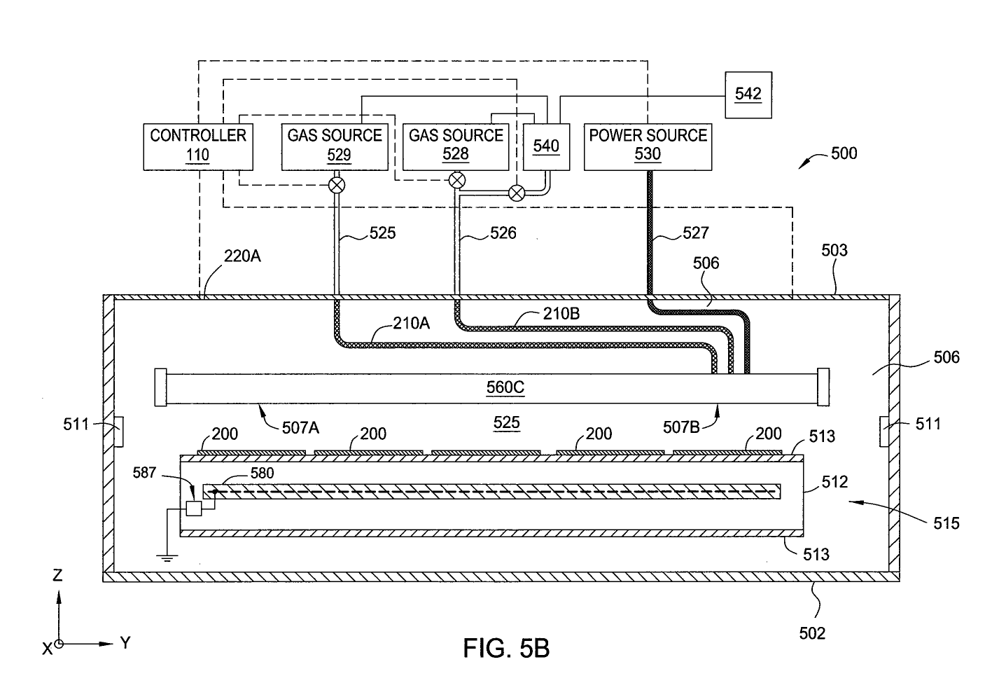

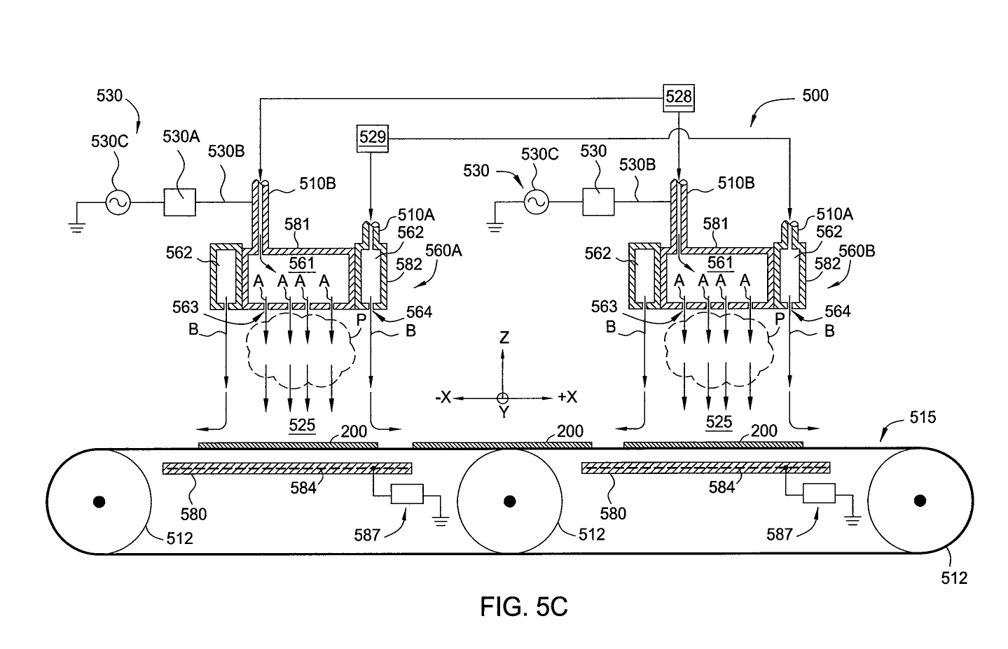

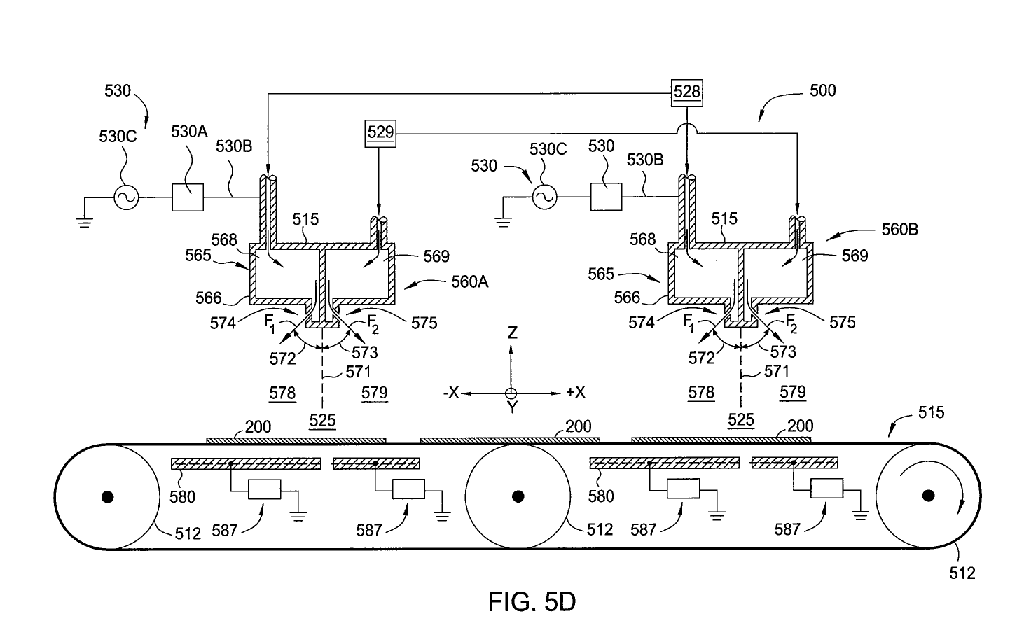

In certain embodiments, as illustrated in FIGS. 2A-2B, the substrate processing system 100 has a processing region 210 through which the linear array of substrates are transferred during processing in a direction “M” from the substrate receiving chamber 105 to the substrate unload chamber 195 using the substrate automation system 515 (FIGS. 5A-5C). As illustrated in FIGS. 1-2C, the substrate receiving chamber 105 and the substrate unload chamber 195 each have at least one substrate transferring region, such as substrate transfer regions 104A, 104B, 108A and 108B, that are positioned on a side of the substrate automation system 515. However, this configuration is not intended to be limiting as to the scope of the invention described herein.

Referring to FIG. 2A, in one embodiment, the substrate receiving chamber 105 comprises one or more automation devices, such as actuator assembly 122 that is configured to receive substrates (e.g., substrates 200) from a substrate transport interface 121 and position them on a portion of the substrate automation system 515 so that they can be transferred through the various processing chambers found in the processing system 100. The substrate transfer interface 121 will generally receive substrates from an upstream location (e.g., an upstream processing module in a solar cell fabrication line). In operation, the substrate automation system 515 is generally loaded with unprocessed substrates 200 in the substrate receiving chamber 105. In one embodiment, the substrates 200 are transported to the substrate transport interface 121 via one or more modular substrate conveyors 123 that are configured to receive cassettes or stack boxes containing multiple substrates 200. In one embodiment, the actuator assembly 122 may be SCARA, six-axis, parallel, belt type conveyor or linear type robots that is adapted to transfer substrates from substrate transport interface 121 to a portion of the substrate automation system 515. In one example, the actuator assembly 122 is a Quattro Parallel Robot that are available from Adept Technology, Inc. of Pleasanton, Calif. In another example, the actuator assembly 122 comprises one or more roller or belt conveyors that are available from the Applied Materials Italia S.r.l. division of Applied Materials, Inc. of Santa Clara, Calif.

In one embodiment, the substrate automation system 515 has a first end 209 where substrates 200 enter the substrate automation system, and a second end 211 where the processed substrates 200, having materials deposited thereon, are removed from the substrate automation system 515. At the first end 209 an input conveyor 220 contained in the substrate automation system 515 supports and guides substrates 200 into the dynamic load lock chamber 120, which then transfers the substrates 200 into the preprocessing chamber 130. A series of intermediate conveyors 221 are generally used to support and guide the substrates through the various processing chambers found in the processing system 100. At the second end 211, an exit conveyor 222 contained in the substrate automation system 515 receives the substrates 200 that have been processed in the processing system 100. While the substrate automation system 515 has been shown with a number of individual conveyors 220, 221 and 222, a single conveyor with a continuous web of material that extends between the first end 209 and second end 211 may be used.

In one configuration, the conveyors in the substrate automation system 515 include support rollers 512 (FIGS. 5A-5C) that support and drive a supporting material that is configured to support the substrates. In one example, the supporting material comprises a continuous web 513 of material that is capable of withstanding the processing environment gases and temperatures achieved by the substrates during processing (e.g., stainless steel mesh, high temperature polymeric materials). When individual conveyors 220, 221 and 222 are used, the rollers 512 may be mechanically driven by a common drive system (not shown) such that they are moved in unison. The various drive signals for the rollers 512, transfer ports 418 and other system actuators are provided by a system controller 110. While in the embodiment illustrated in FIGS. 1-2B, has seven deposition and processing chambers, this configuration is not intended to be limiting as to the scope of the invention, since any number of chambers may be provided depending on the number of processes and the required equipment for each process. Some examples of other possible processing system configurations are illustrated in FIGS. 7A-7C.

In one embodiment, the substrate automation system 515 is configured to rapidly transfer one or more rows of substrates 200 through the processing region 210 of the processing system 100. In one example, as illustrated in FIG. 2A, the substrate automation system 515 is adapted to transfer multiple rows of substrates 200 that are serially transferred from the first end 209 to the second end 211 through the processing region 210. However, one will note that while five rows (i.e., rows R₁-R₅) of substrates are illustrated in FIG. 2A, fewer or greater numbers of rows of substrates may be sequentially processed without deviating from the scope of the invention described herein. In one example, as illustrated in FIG. 2B, the substrate automation system 515 is adapted to transfer two rows of substrates 200 (i.e., rows R₁-R₂) that are serially transferred from the first end 209 to the second end 211. In another example, as illustrated in FIG. 7A, a substrate automation system 515 is adapted to transfer a single row of substrates 200 (i.e., row R₁) that are serially transferred through the processing region 210 from the first end 209 to the second end 211.

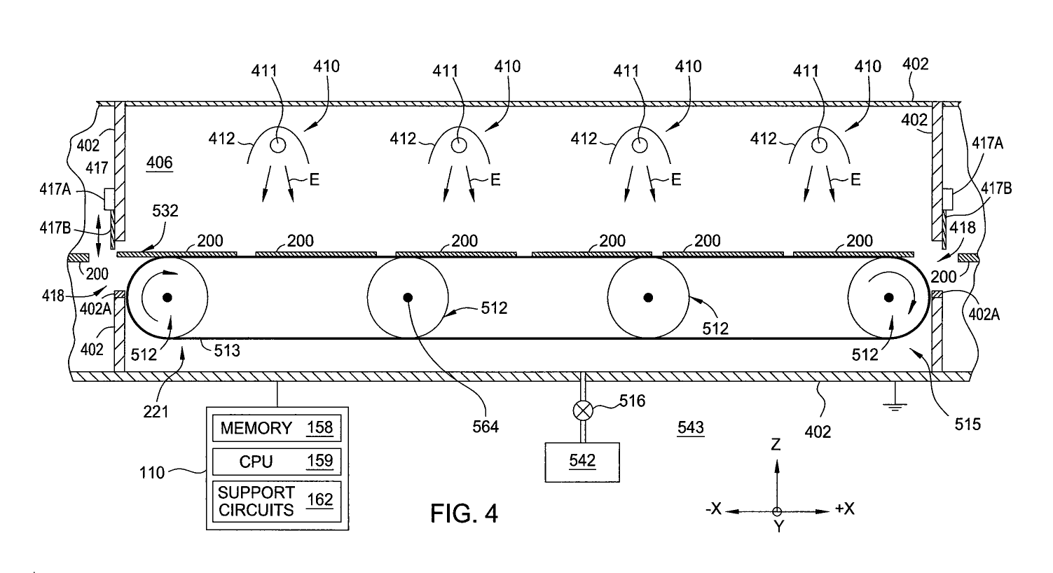

It has been found that to achieve a desirable substrate throughput to meet current solar cell processing cost targets, such as processing >3000 substrates per hour, and minimize cost, it is desirable to limit the number to rows of substrates that are serially processed to between about one to three rows of substrates. Thus, in one example, as shown in FIG. 2B, the substrate automation system 515 is adapted to transfer two rows R₁ and R₂ of substrates through the processing region 210 found in the processing system 100. It believed that processing substrates in single row, or even two or three rows, has an advantage over configurations that transfer more than three serial rows of substrates (e.g., greater than 5 rows). This belief is due to the required high relative speeds of the support robotics (e.g., actuator assembly 122) required to reliably work together to achieve the high system throughput of the fragile solar cell substrates, the need to effectively maintain the processing environment in the processing region 210 (e.g., deposition chambers) at a moderate vacuum level (e.g., 1-100 mTorr) during processing, the structural integrity of the chamber components (e.g., walls 202 and ports 517) required to process multiple rows at one time, and the material cost issues created by the sizing of the chamber components (e.g., walls 202, vacuum pumps 542, ports 517, valves) to process the multiple rows of substrates at the various high processing temperatures and vacuum pressures required to form various layers on the solar cell substrate, as discussed below. One will note that the ability to maintain the processing environment at a moderate vacuum level becomes drastically harder as the width of the opening required to receive the rows of substrates increase (e.g., size of the substrate transfer ports 418 in the Y-direction in FIGS. 2A-2B and 4), due to non-linear increase in pumping capacity required to achieve a moderate vacuum pressure in the processing region of the processing chamber(s) as the opening's cross-sectional area increases (e.g., orifice size). As illustrated in FIGS. 2A-2B, the width, and, thus, volume of the processing regions of the deposition and processing chambers can be reduced by the proper selection of the number of rows of substrates that are serially delivered through the system in an effort to improve substrate throughput, reduce system cost, improve deposition and processing chambers' structural integrity and improve device yield (e.g., reduce robot transferring errors, reduce automation induced contamination). In one example, the required width W₁ of a processing system having five rows is greater than the required width W₂ of a processing system that has two rows. The reduction in width of the processing system will also improve the system serviceability, reduce maintenance time to fix system problems and reduce the system start-up time after maintenance was performed on one of the chambers, due to the smaller amount of chamber volume and wall surface area that can outgas when it is pumped down to a vacuum pressure and the smaller amount of material that must be cooled down for service or heated up for operation.

Referring to FIGS. 2A-2B, in one configuration, the substrate unload chamber 195 comprises one or more automation devices, such as actuator assembly 122 which are discussed above, that are configured to transfer the processed substrates (e.g., substrates 200) from the substrate automation system 515 to a substrate transport interface 126. The substrate transfer interface 126 will generally transfer substrates to a downstream location (e.g., a downstream processing module in a solar cell fabrication line). In operation, the actuator assembly 122 will generally remove the processed substrates 200 from the second end 211 and transfer them out of the processing system 100. In one embodiment, the substrates 200 are transported from the substrate transport interface 126 position via one or more modular substrate conveyors 127 that are configured to transfer the received cassettes or stack boxes containing multiple substrates to other parts of the solar cell fabrication plant.

In one embodiment, the chambers 130-190 disposed in the processing system 100 are selectively isolated from each other by use of slit valve assemblies 417, which are discussed below. Each slit valve assembly 417 is configured to selectively isolate the processing region in one of the chambers 130-190 from the substrate automation system 515 and is disposed adjacent to the interface between the chambers 130-190 and the substrate automation system 515. In one embodiment, the substrate automation system 515 is maintained within a vacuum environment to eliminate or minimize pressure differences between the transfer chamber 110 and the individual chambers 130-190, which are typically used to process the substrates under a vacuum condition. However, in an alternate embodiment, the transfer region 210 and the individual chambers 130-190 may be used to process the substrates in a clean and inert atmospheric pressure environment.

Generally, the processing system 100 includes a system controller 110 configured to control the automated aspects of the system. The system controller 110 facilitates the control and automation of the overall substrate processing system 100 and may include a central processing unit (CPU) (not shown), memory (not shown), and support circuits (or I/O) (not shown). The CPU may be one of any form of computer processors that are used in industrial settings for controlling various chamber processes and hardware (e.g., conveyors, motors, fluid delivery hardware, etc.) and monitor the system and chamber processes (e.g., substrate position, process time, detector signal, etc.). The memory is connected to the CPU, and may be one or more of a readily available memory, such as random access memory (RAM), read only memory (ROM), floppy disk, hard disk, or any other form of digital storage, local or remote. Software instructions and data can be coded and stored within the memory for instructing the CPU. The support circuits are also connected to the CPU for supporting the processor in a conventional manner. The support circuits may include cache, power supplies, clock circuits, input/output circuitry, subsystems, and the like. A program (or computer instructions) readable by the system controller 110 determines which tasks are performable on a substrate. Preferably, the program is software readable by the system controller 110, which includes code to generate and store at least substrate positional information, the sequence of movement of the various controlled components, and any combination thereof.

FIGS. 1 and 2A-2B are schematic views of one embodiment of a substrate processing system 100 that includes multiple processing chambers (e.g., reference numerals 140, 160 and 180). While the type of processing technique performed in the processing chambers 140, 160 and 180 disposed in the processing system 100 may include PVD, PECVD, a LPCVD, etc., as discussed above, it is believed that a PECVD deposition chamber, which is similar to one of the configurations illustrated in FIGS. 5A-5D, is advantageous to form high quality layers on both surfaces of a solar cell substrate 200.

FIG. 2C is a side cross-sectional view of a portion of the substrate processing system 100 illustrated in FIG. 2B. One will note that the processing chamber 170 illustrated in FIG. 2B has been removed for clarity reasons from the side cross-sectional view illustrated in FIG. 2C, however, in some configurations the process chamber 170 can be positioned between the processing chambers 160 and 180 to control the temperature of the substrates entering the processing chamber 180. In one configuration of the processing system 100, as shown in FIG. 2C, a plurality of processing chambers are disposed such that the individual conveyors 220, 221 and 222, within the substrate automation system 515, are adapted to transfer the substrates through each of the different portions of processing region 210 found within the processing system 100. The processing region 210 may comprise processing regions 131, 141, 151, 161, 171, 181 and 191 (FIGS. 2A-2B), which are found in the selectively isolatable processing chambers 130-190. The portions of the processing region 210 may be intermittently isolatable from each other by use of one or more slit valve assemblies 417 disposed at the entrance and/or exit of each of the processing chambers 130-190. While the slit valve assemblies 417 are discussed in conjunction with the processing chamber 400, which are schematically illustrated in FIG. 4, this configuration is not intended to be limiting as to number and/or positions where the slit valve assemblies can be used in the processing system 100. In one embodiment of the processing system 100, each of the slit valve assemblies 417 are closeable and are mounted on one of the processing chamber walls. The slit valve assemblies 417, which may be used in conjunction with any of the processing chambers discussed herein, may contain a closeable door 417B that forms a seal with a portion of the wall 402 by use of an elastomeric strip 402A disposed on top of the wall 402 to seal the substrate transfer port 418. An actuator 417A, extends and retracts the door 417B, based on commands received from the support circuits 162 of the system controller 110. When the door 417B is in the closed position, the processing chamber is sealed so that regions on either side of the door 417B are isolated from each other. In one embodiment, the door 417B is a conventional gate valve that is configured to prevent gas leakage through the substrate transfer port 418. During processing the doors 417B may be closed so that one or more substrate processing steps may be performed in the portion of the processing region 210 disposed between the processing chamber walls 402. After the process associated with each chamber is performed, the doors 417B of each chamber are opened. The conveyors 220, 221 and 222 advance the substrates 200 in the direction “M” into the subsequent processing chamber, based on commands received by a drive mechanism from the support circuits 162 of the system controller 110. However, in some configurations, the substrate transfer ports 418 remain at least partially open during substrate processing, and, thus, only obstruct the movement of the substrates (i.e., transfer ports are “closed”) when maintenance activities are performed on the processing system.

### Substrate Processing Chamber Designs

FIG. 4 is a side cross-sectional view of one embodiment of a processing chamber 400 that may form one or more of the processing chambers, such as processing chambers 130-190 (FIGS. 1-2B), disposed in the processing system 100. FIG. 4, is a side cross-sectional view of the processing chamber 400 that is aligned relative to the transfer direction, or parallel to the X-direction of the processing system 100. In one embodiment, the processing chamber 400 comprises one or more energy sources, such as sources 410, chamber walls 402 that at least partially enclose a portion of the processing region 210, or processing region 406, and at least a portion of the substrate automation system 515. The walls 402 generally comprise a material that can structurally support the loads applied by the external environment 543, which is external to the processing region 406, when it is heated to a desirable temperature and pumped to a vacuum pressure by a vacuum pump 542. The walls 402, which are similar to the walls 202 shown in FIG. 2A, generally comprise a material such as an aluminum material or stainless steel.

In one configuration, the sources 410 each comprise a reflector 412 and a radiant source, such as an IR lamp, tungsten lamp, arc lamp, microwave heater or other radiant energy source that is configured to deliver energy “E” to a surface of the substrates 200 disposed in the processing region 406 of the processing chamber 400 as they are transferred by the substrate automation system 515. During processing, the processing chamber 400 can be used to deliver a desired amount of energy to the substrates 200 prior to the substrates being received by a subsequent processing chamber, such as the deposition chamber 140, 160 or 180, so that the substrates reach a desired processing temperature when they enter the processing region of the subsequent processing chamber.

FIGS. 5A-5C are side cross-sectional views of one embodiment of a processing chamber 500 that may be positioned within or replace one or more of the processing chambers, such as processing chambers 140, 160 and 180 (FIGS. 1-2B) disposed in the processing system 100. FIG. 5A, is a side cross-sectional view of the processing chamber 500 that is aligned relative to the transfer direction, or parallel to the X-direction of the processing system 100. FIG. 5B is a side cross-sectional view of the processing chamber 500 that is aligned relative to a direction that is orthogonal to the transfer direction, or parallel to the Y-direction. In one embodiment, the processing chamber 500 comprises one or more deposition sources, such as deposition sources 560A-560D shown in FIG. 5A, gas sources 528 and 529, a power source 530, chamber walls 502 that at least partially enclose a portion of the processing region 210 (e.g., processing region 506), and at least a portion of the substrate automation system 515. FIG. 5C is a close-up side cross-sectional view of two deposition sources 560A and 560B that are intended to form a layer on the surface of the substrates 200 as they pass under the deposition sources. The walls 502 generally comprise a material that can structurally support the loads applied by the environment 543, which is external to the processing region 506, when it is heated to a desirable temperature and pumped to a vacuum pressure by a vacuum pump 542. The walls 502, which are similar to the walls 202 shown in FIG. 2A, generally comprise a material such as an aluminum material or stainless steel.

In one configuration, the portion of the substrate automation system 515 comprises an intermediate conveyor 221 that is adapted to support, guide move the substrates 200 through the processing chamber by use of one or more actuators (not shown), for example, a stepper motor or servo motor. In one configuration, the intermediate conveyor 221 comprises a two or more rollers 512 and a belt 513 that are configured to support and move the rows of substrates 200 in a positive +X-direction during processing.

In one embodiment of the processing chamber 500, each of the deposition sources 560A-560D are coupled to at least one gas source, such as gas sources 528 and 529, that is configured to deliver one or more processing gases to a processing region 525 formed with the processing region 506, and below each of the deposition sources and over the surface of a substrate 200 disposed there under. As illustrated in FIG. 5B, the deposition sources 560A-560D are generally configured to extend over the substrates 200 disposed on the substrate automation system 515.

As illustrated in FIG. 5C, the deposition sources, will generally comprise at least one gas delivery element, such as a first gas delivery element 581 and second gas delivery element 582, which are each configured to direct the processing gases to the processing region 525. The first gas delivery element 581 comprises a fluid plenum 561 that is configured to receive the process gas from a gas source 528 and deliver the received gas to the processing region 525 through a plurality of holes 563 formed therein. Similarly, the second gas delivery element 582 comprises a fluid plenum 562 that is configured to receive the process gas from a gas source 529 and deliver the received gas to the processing region 525 through a plurality of holes 564 formed therein. The gas sources 528 and 529 are generally configured to provide one or more precursor gases and/or carrier gases that are used to deposit a layer on the surface of the substrates 200 by use of a PECVD process. In one process sequence, at least one of the gas sources 528 and 529 is configured to deliver a silicon containing gas to a deposition source, such as silane (SiH₄), a nitrogen containing gas, such as nitrogen (N₂) or ammonia (NH3), to form a silicon nitride layer on the surface of the substrates. In one process sequence, at least one of the gas sources 528 and 529 is configured to deliver an aluminum containing gas to a deposition source, such as trimethylaluminum (TMA), and an oxygen containing gas, such as oxygen (O₂), to form an aluminum oxide layer (AlₓO_{y}) on the surface of the substrates.

In one configuration, as shown in FIG. 5C, the power source 530 is configured to deliver RF energy to the processing region 525 by use of an RF power supply 530C, an optional match 530A (e.g., matching network) and electrical connection 530B to form a plasma “P” within the processing region 525 to enhance the deposition process being performed on the substrates 200. In one embodiment, an electrical bias is applied an electrode 580 disposed within the processing region 506 to help improve the properties of the deposited film. In one configuration, a bias is applied to the electrode 580 by use of an electrical source 587 (FIG. 5A) that may comprise an active electrical biasing source (e.g., AC or DC power supply) or switch that selectively grounds portions of the electrode 580. In one embodiment, the electrode 580 may include a heating element 584, such as resistive heating element 584 that may be powered by a separate heater power supply (not shown). The electrode 580 is positioned proximal to the substrates 200 in order to heat the substrate 200 to a temperature of about 200° C. to about 550° C. during processing. The electrode 580 and/or heating element 584 may be fabricated from an electrically conductive material to function as a ground or radio frequency (RF) electrode to act as an electrode in a capacitively coupled plasma.

In another processing chamber configuration, as shown in FIG. 5D, the deposition sources 560A-560D shown in FIG. 5A may comprise a fluid distribution source 565 that is configured to deliver precursor gasses in at least two different directions, such as the two different directions F₁ and F₂ relative to the substrate movement direction +X-direction. FIG. 5D is a side cross-sectional view of the processing chamber 100 aligned relative to the transfer direction, or parallel to the X-direction. The fluid distribution source 565 further comprises a dual gas injection manifold 566 having two discrete flow channels 574 and 575 formed therein. The flow channel 574 is coupled to the first gas source 528 and the flow channel 575 is coupled to the second gas source 529. The first gas source 528 and the second gas source 529 are generally configured to deliver one or more precursor gases or carrier gases to the dual gas injection manifold 566. The first gas source 528 and the second gas source 529 may each be adapted to deliver a processing gas that comprises a gas selected from the group comprising a silicon containing gas (e.g., silane (SiH₄)), ammonia (NH₃), an aluminum containing gas (e.g., trimethylaluminum (TMA)), oxygen (O₂), nitrogen (N₂), hydrogen (H₂), and combinations thereof or derivatives thereof.

The first gas source 528 and the second gas source 529 are coupled to the flow controller (not shown). The flow controller may comprise a series of controlled valves or mass flow controllers configured to control the flow rate of the precursor gases from the first gas source 528 and the second gas source 529 to the gas injection manifold 566. Each of the flow channels 574, 575 may include a plurality of discrete holes that are formed through portions of the fluid distribution source 565 to direct the flowing gases in the desired directions F₁ or F₂ from the plenums 568 and 569, respectively, into the processing region 525. In one embodiment, each of the fluid distribution sources 565 may contain a plurality of separately isolated plenums, such as plenums 568, 569 that are distributed in the Y-direction, and are each adapted to separately deliver one or more process gases from their flow channels in either the flow direction F₁ and/or the flow direction F₂. The flow rate of the gases delivered from the first gas source 528 and the second gas source 529 can each be controlled to provide a desired gas composition to be delivered from the flow channel 574 or the flow channel 575.

In one configuration, each of the fluid distribution sources 565 are configured to deliver a non-symmetric fluid distribution and/or gas composition to the space within the processing region 525 to create non-uniform deposition on the substrate 200 as the substrate 200 is moved relative to each of the fluid distribution sources 565. Due to the configuration of the flow channels 574 and 575, and/or the configuration of the power source 530, the processing region 525 may be effectively split into two or more regions, thus allowing the process variables in each region to be varied and controlled independently. In one configuration of the processing chamber 100, the fluid distribution source 565 is configured to divide the processing region 525 into a first plasma volume 578 and a second plasma volume 579 by use of RF energy delivered by an RF power supply 530C, an optional match 530A and electrical connection 530B. In one example, portions of the processing region 506 may be divided into two sections that are separated by an imaginary vertical plane 571 (e.g., parallel to the Y-Z plane in FIG. 5D). In one embodiment, an electrical bias is applied an electrode 580 disposed within the processing region 506 to help improve the properties of the deposited film. In one configuration the electrode 580 may have separate electrode elements 585A, 585B that are configured to separately alter the plasma formed in the first plasma volume 578 or the second plasma volume 579.

The first plasma volume 578 differs from the second plasma volume 579 by properties of the plasma created by the fluid distribution source 565. For example, the first plasma volume 578 may have a lower plasma density (i.e., ions per unit area), a lower flux (i.e., ion density per unit area/time), or combinations thereof, as compared to the second plasma volume 579. Alternatively, the second plasma volume 579 may have a lower plasma density and/or a lower flux than the first plasma volume 578. Due to the configuration of the fluid distribution source 565 and the separation of the processing region 525 into the first plasma volume 578 and the second plasma volume 579, a user may vary the deposition process parameters, which, in one embodiment, facilitates formation of a film having a graded composition on the substrate 200.

In one embodiment, the pressure in the processing region 525 can be adjusted by the vacuum pump 542 (FIG. 5A) to provide a desired gas flow regime in the processing region 525 to enhance the quality or properties of the deposited film. In one example, a low pressure is created in the processing region 525 (e.g., less than about 500 mTorr) to provide a laminar flow of reactants (e.g., precursor gases) and also prevent the amount of mixing of reactants between the first plasma volume 578 and the second plasma volume 579 across the imaginary vertical plane 571. Additionally, the flow channels 574 and 575 may be positioned to direct the flow of gases towards different regions of the substrate 200 as they are transferred through the processing region 506. In one embodiment, the flow channels 574 and 575 include a plurality of openings that are formed at an angle 572 and 573, respectively, of about 30 degrees to about 45 degrees relative to the imaginary vertical plane 571 (e.g., either in the −X direction or the +X direction).

Therefore, the fluid distribution source 565 can be used to form a graded film that may consist of a single film layer that has regions having a different chemical compositions and/or crystal structure. In one embodiment, the graded film may have regions with differing chemical compositions and/or crystal structure in a direction that is parallel to the deposited film thickness (e.g., parallel to the Z-direction in FIG. 5A). The graded film may consist of layers that are deposited one after the other as the substrate 200 moves in the X-direction relative to the fluid distribution source(s) 565. The deposition of each layer, or a portion of a layer, is temporally separated due to the orientation of the flow channels 574, 575 and the speed of the substrate 200 as the substrate 200 moves relative to a fluid distribution source 565. In one embodiment, the second flow rate of the precursor gases from the second gas source 529 is greater than the first flow rate of the precursor gases from the first gas source 528. Thus, the first precursor gas is flowed to the processing region 525 at a higher rate than the second precursor gas, which provides a higher plasma density and/or a higher flux in the second plasma volume 579 as compared to the first plasma volume 578 and may form a film having differing composition. A graded film may be formed by the same or different precursors. In one embodiment, the graded film may be one or more layers of hydrogenated silicon nitride (Si_{X}N_{Y}:H) having different concentrations of hydrogen and/or Si:N bonds throughout. In another embodiment, the graded film may be aluminum oxide (Al_{X}O_{Y}) having different stoichiometry, such as differing ratios of aluminum to oxygen. While a slight temporal separation will be encountered by the material layers formed on the substrate 200, a single continuous film may be formed on the surface of the substrate 200. In one example, a first flow rate of precursor gases from the first gas source 528 and a second flow rate of precursor gases from the second gas source 529.

The combination of the deposition sources 560A and 560B may be utilized to form a graded film on the substrate 200 by facilitating formation of the first plasma volume (e.g., plasma volume 578 below the first deposition source 560A), the second plasma volume (e.g., plasma volume 579 below the first deposition source 560A), a third plasma volume (e.g., plasma volume 578 below the second deposition source 560B) and a fourth plasma volume (e.g., plasma volume 579 below the second deposition source 560B). Each of the first plasma volume, the second plasma volume, the third plasma volume or fourth plasma volume may contain a different plasma density and/or a different flux to facilitate deposition of a first and second layer at different deposition rates on the substrate 200. In one embodiment, one or both of the deposition source 560A and the deposition source 560B may be coupled to an actuator that is movable at least vertically. The actuator may be utilized to adjust spacing between the substrate and the respective fluid distribution source 565. This allows additional process control by varying the spacing between the respective dual gas injection manifold and the substrate 200.

It is believed that by using at least two deposition sources 560A, 560B, 560C, 560D to process or deposit a layer on the substrates in a serial manner the properties of the deposited layer can be greatly improved over conventional processing techniques. The ability to separately control the processing conditions and gas concentrations within different regions of the processing chamber, while the substrates are being rapidly transferred through the processing region 210, allows the material deposited on the surface of the substrate at different times to be easily controlled. Thus, by use of two or more deposition sources, films that have differing composition, graded composition and/or differing physical structure (e.g., mass density, crystal structure) can be created during the deposition sequence performed in the processing system. In one example, a high quality passivation layer is first deposited on the surface of a substrate, such as the first layer 321 that is disposed on the substrate surface 305 of the substrate 310 (FIG. 3), is deposited at a first deposition rate using a first mixture of processing gasses and plasma power, and then a lower quality passivation layer is deposited over the surface of the high quality passivation layer, such as the second layer 322 illustrated in FIG. 3, is deposited at a second deposition rate, which is higher than the first deposition rate, using a second mixture of processing gases and plasma power.

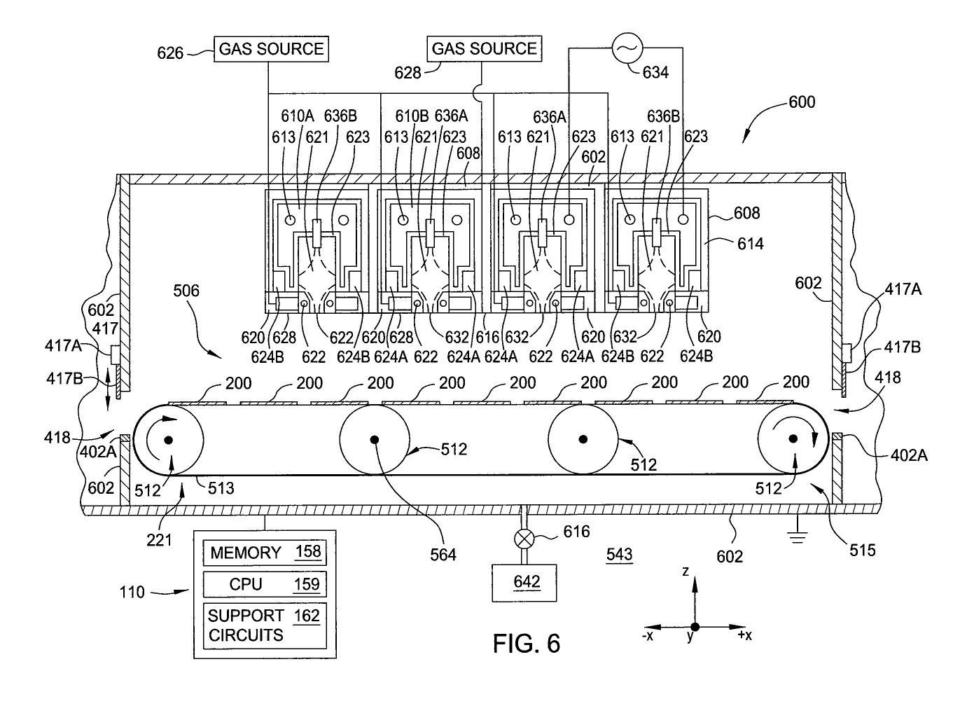

FIG. 6 is a side cross-sectional view of one embodiment of a processing chamber 600, that may be positioned within or replace one or more of the processing chambers, such as processing chambers 140, 160 and 180 (FIGS. 1-2B) disposed in the processing system 100. FIG. 6, is a side cross-sectional view of the processing chamber 600 that is aligned relative to the transfer direction, or parallel to the X-direction of the processing system 100. In one embodiment, the processing chamber 600 includes one or more energy sources, such as sources 612 and 614, chamber walls 602 that at least partially enclose a portion of the processing region 210, or processing region 606, and at least a portion of the substrate automation system 515. The walls 602 generally are constructed from a material that can structurally support the loads applied by the external environment 643, which is external to the processing region 606, when it is heated to a desirable temperature and pumped to a vacuum pressure by a vacuum pump 642. The walls 602, which are similar to the walls 202 shown in FIG. 2A, may be constructed from a material such as an aluminum material or stainless steel.

In the configuration shown in FIG. 6, the sources 612, 614 are “Hall effect” plasma sources. In this type of source, a first source 612 is surrounded by a second source 614. A nozzle 616 is shown for introducing processing gas into the processing region 606. A gas source 628 is present to deliver the processing gas through the nozzle 616. Each source 612, 614 includes an outer shell 608 that encloses an electrode 610A, 610B. Each electrode 610A, 610B has cooling passages 613 formed therein. The electrodes 610A, 610B are coupled to a common power supply 634 and, in operation, driven in opposite phases. In one embodiment, the power supply 634 is an AC power supply

Gas is also introduced to the sources 612, 614 from a gas source 626 through a gas manifold 628 formed in a plate 620. The plate 620 is cooled by cooling fluid flowing through cooling channels 622. The plate 620 is coupled to the outer shell 608 by well know fastening mechanisms (not shown) such as screws. The plate 620 has an opening therethrough that forms a nozzle 622.

Each source 612, 614 has a cavity portion 621 that is bound by a liner 623 that covers the electrodes 610A, 610B. The electrodes 610A, 610B are shaped to form the cavity portion. The liner 623 facilitates heat transfer in the sources 612, 614. Magnets 624A, 624B are disposed adjacent an end of the cavity portion 621 and adjacent the plate 620. The magnets 624A, 624B may include permanent magnets or magnetrons. The magnets 624A, 624B are opposite polarity. Additionally, magnet shunts 636A, 636B are present within the cavity portion 621 and coupled to the electrodes 610A, 610B. The magnet shunts 636A, 636B are opposite polarity to the respective magnets 624A, 624B. Collectively, the magnets 624A, 6242B and the shunts 636A, 636B shape a magnetic field that affects the deposition.

The two electrodes 610A, 610B are connected on opposite sides of the AC power supply 634. Reactive and/or inert gases are introduced into cavity portions 621 via the gas manifolds 628. Simultaneously, a second gas is introduced through the nozzle 616. The electrodes 610A, 610B each alternate as the cathode and the anode during processing. While one electrode 610A, 610B is a cathode, the other electrode 610A, 610B is the anode for the circuit. The two sources 610A, 610B, by alternating as anode and cathode, prevent buildup of material on the liner 623 because any buildup is continuously removed.

The sources 612, 614 generate an ion beam for depositing material onto the substrates 200. While operating as an anode, all electrons from the source 612 must flow to the source 614 to return to the power supply 624. To reach the internal electrode 610A, 610B, the electrons must enter cavity portion 621 through the nozzle 632. As electrons move toward the nozzle 632, the electrons are impeded by a positively charged electric field emanating through the nozzle 632. The positively charged electric field is created by the strong magnetic field in the nozzle 632 extending out to a weaker field region closer to the substrates 200. As electron current flow is impeded across the positively charged electric field, a voltage drop is produced.

As electrons are being impeded from flowing into the cavity portion 621, gas atoms are flowing out of the cavity portion 621 through the nozzle 632. These neutral atoms collide with electrons such that ions are formed. The ions are then accelerated out of the source 612, 614 toward the substrates 200. This overall effect is similar to ion sources employing the “End Hall” effect with an axial electron mirror confinement. In operation, a dense, linear beam of ions flows out of the sources 612, 613 toward the substrates 200 on each half cycle. At the same time electrons flowing out of the cathode source 612, 614 neutralize the generated ion beam. The result is an ideal neutralized, uniform, dense beam directed at the substrates 200.

As shown in FIG. 6, the first source 612 is surrounded by the second source 614. Thus, when the first source 612 is operating as the cathode, the anode surrounds the cathode. Conversely, when the second source 614 operates as the cathode, the anode is surrounded by the cathode. The quick cycling between cathode and anode causes the electrons to continuously shift between adjacent sources 612, 614.

In operation, the two sources 612, 614 operate collectively to deposit a uniform film on each of the substrates 200. A processing gas is introduced through the nozzle 616 from the gas source 628. Simultaneously, a reactive gas and/or inert gas is introduced through the manifold 618 in top plate 620 from the gas source 626. As the gas is introduced through the manifold 618 and the nozzle 616, power is applied to the electrodes 610A, 610B from the power source 624. The electrodes 610A, 610B are driven in opposite phases such that one electrode 610A, 610B operates as an anode, while the other electrode 610A, 610B operates as a cathode. The electrical bias to the electrodes 610A, 610B causes electrons to be generated by the source 612, 614 operating as a cathode that collect near the nozzle 616 of the source 612, 614 operating as a cathode that collect near the nozzle 616 of the source 612, 614 operating as an anode. The electrons cannot penetrate into the cavity portion 621 of the anode source 612, 614 due to the magnetic field generated by the magnets 624A, 624B and shunt 626A, 626B. Simultaneously, gas atoms introduced from the manifold 618 are flowing out of the nozzle 632. The gas atoms collide with the electrons and generate ions. The ions are then accelerated towards the substrates 200 due to the potential difference between the electric field created by the electrons collected near the nozzle 632 and the bias applied to the electrode 610A, 610B. The ions generate a plasma plume that permits even deposition on all of the substrates 200.

In one process sequence, at least one of the sources 612 and 614 is configured to deliver a silicon containing gas to a deposition source, such as silane (SiH₄), a nitrogen containing gas, such as nitrogen (N₂) or ammonia (NH3), to form a silicon nitride layer on the front surface (e.g., the front surface 305) of the substrates 200.

As further shown in FIG. 6, a portion of the substrate automation system 515 includes an intermediate conveyor 221 that is adapted to support, guide, and move the substrates 200 through the processing chamber 600 by use of one or more actuators (not shown), for example, a stepper motor or servo motor. In one configuration, the intermediate conveyor 221 comprises support rollers 512 and a the web 513 of material that are configured to support and move the rows of substrates 200 in a positive +X-direction during processing.

In one embodiment, the pressure in the processing region 606 is adjusted by the vacuum pump 642 to provide a desired gas flow regime in the processing region 606 to enhance the quality or properties of the deposited film. In one example, a low pressure is created in the processing region 606 (e.g., less than about 500 mTorr) to provide a laminar flow of reactants (e.g., precursor gases).

### Substrate Reorienting Chamber

Referring FIG. 7A-7B, in one embodiment, the processing system 100 may further include a processing chamber 700 for reorienting, or flipping, the substrates 200 disposed in a vacuum environment within a portion of the processing region 210, or processing region 701, such as the processing chamber 150. In some embodiments, a portion of the linear array of substrates 200, having been processed on one side, may then be transferred into the processing chamber 150 for reorienting the substrates 200 such that the opposite side may be processed in the downstream processing chambers. For instance, if an upwardly facing side of each substrate is first processed, the processing chamber 150 reorients each of the substrates 200 such that the previously upwardly facing side faces downwardly and the previously downwardly facing side faces upwardly for subsequent processing. After reorienting the substrates 200, the substrates 200 may then be transferred into subsequent processing chambers, such as processing chambers 160-190 for processing the opposite side of the substrates 200. In one embodiment, the substrates 200 are transferred into processing chamber 160, such as a PECVD chamber, and a deposition process is performed on the substrates 200. Thus, processing a first side of the substrates 200, then flipping of the substrates 200, and processing of the opposite side of the substrates 200 may all be achieved within the processing system 100 without breaking vacuum within the system.

FIG. 7A is an isometric view of a portion of the processing chamber 700 that comprises a substrate reorientation device 705. A substrate reorientation device 705 may comprise a rotational actuator 720, tandem conveyor assemblies 710A and 710B, and support 780 that are all coupled to the system controller 110. In one configuration of a substrate inverter system 705 the tandem conveyor assemblies 710A and 710B are positioned coplanar with the substrate transfer direction 708 (e.g., X-direction in FIGS. 5A and 6). The system controller 110, using rotational actuators (not shown) mounted inside each conveyor assembly 710A and 710B activates the conveyor belts 770 to facilitate loading and dispensing substrates along the substrate transfer direction 708. If substrate inverting is required, the conveyor belts 770 are halted when the group of substrates, such as rows R₁-R₅ and one or more columns of substrates (X-direction), are positioned between the conveyor belts 770, so that a vacuum gradient may be applied to further secure the substrate to at least one of the conveyor belts 770. The substrate inverter system 700 inverts the substrate by rotating the tandem conveyors in unison using a rotational actuator 720 (FIG. 7A) that is coupled to the supporting structural elements within each of the conveyor assemblies 710A and 710B. The inverting operation can be performed about any rotation axis on, or proximate to, the centerline of the group of the substrates. In this embodiment, inverting rotation “R” (FIG. 7B) takes place about substrate centerline “Y” (FIG. 7B) which lies 90 degrees from the substrate transfer direction 708. Inverting substrates about any axis which is consistent with substrate centerline results in the pre-inverted leading edge of the substrate becoming the post inverted trailing edge, with respect to the substrate transfer direction 708. In automated substrate production systems, control of substrate edge orientation with respect to the substrate transfer direction 708 may be desirable for processing. Additionally, this method allows substrates traveling on the substrate transfer direction 708 to be loaded, inverted, and unloaded from either side of the tandem conveyor assemblies 710A and 710B, thus eliminating the time that would otherwise be required to reset the inverter to collect another group of substrates.

FIG. 7B illustrates a schematic cross-sectional view of one embodiment of the conveyor assemblies 710A and 710B disposed in the processing chamber 150. In one embodiment, a conveyor belt 770 is disposed over rollers 711 and 712 contained in conveyor assembly 710A, and a second conveyor belt 770 is disposed over rollers 713 and 714 contained in conveyor assembly 710B. In one embodiment, a first rotational actuator (e.g., electric motor), which is controlled by the system controller 110, is coupled to one of the rollers in the conveyor assembly 710A, and a second rotational actuator (e.g., electric motor), which is also controlled by the system controller 110, is coupled to the rollers in the conveyor assembly 710B. In one embodiment, the conveyor belts 770 in each of the conveyor assemblies 710A and 710B are operated independently, through use of commands sent by the system controller 110 to each of the rotational actuators. In one embodiment, the elastic properties of the conveyor belts 770, in combination with the spacing (i.e., gap formed between the conveyor assemblies 710A and 710B) between the two conveyor assemblies 710A and 710B is used to adjust for variations in substrate thickness, substrate warpage and planarity of the conveyors.

Additionally, each of the conveyor belts 770 may be porous to allow a fluid to be transferred from one side of a conveyor belt 770 to the other. In one embodiment, the conveyor belts 770 are formed from a compliant and porous material, such as a polyurethane foam or metal wire mesh, or other similar material. In one embodiment, the system controller 110 can be used to selectively control the flow of gas between the gas source 791 and the plenums 790 in each of the conveyor assemblies 710A and 710B. In one example, a sub-atmospheric pressure (e.g., vacuum) can be created at one surface of a conveyor belt 770 due to the application of a vacuum applied to an opposing surface that is in fluid communication with a fluid source 791. In one aspect, the substrates are captured and retained on a porous conveyor belt 770 disposed over the supporting surface 792 by providing a vacuum pressure within the ports 794 formed in each of the conveyor assemblies 710A and 710B. In one configuration, the fluid source 791 is a vacuum pump, or vacuum ejector, that is adapted to provide a vacuum to a surface of the conveyor belt 770 from one or more ports 794 formed in the plenum 790. In configurations where the pressure in the processing region 210 is too low to form a desirable “gripping force” by applying a vacuum to one side of the conveyor belt 770, an actuator may be used to reposition at least one of the conveyor assemblies 710A and 710B to close the gap formed between them so that the substrates 200 disposed there between can be restrained from moving during the reorienting process.

In some embodiments of the processing system 100, the processing chamber 700 may further comprise one or more energy sources, such as energy sources 704. The energy sources 704 may comprise similar elements as discussed above in conjunction with the source 410, and thus may each comprise a reflector 412 and a radiant source 411 that are configured to deliver energy “E” to the substrates 200 disposed in the processing region 701 of the processing chamber 700 as they are re-oriented by the substrate reorientation device 705 and transferred by the components found in the substrate automation system 515. In one configuration, an energy source 704 is configured to deliver energy to the substrates received by and/or disposed in the substrate reorientation device 705. The energy sources 704 and system controller 110 are generally used to maintain and/or control the temperature of the reoriented substrates to assure that they will be at a desirable temperature when they are transferred from the processing chamber 700 and/or received by a downstream processing chamber.

### Dynamic Load Lock Chamber

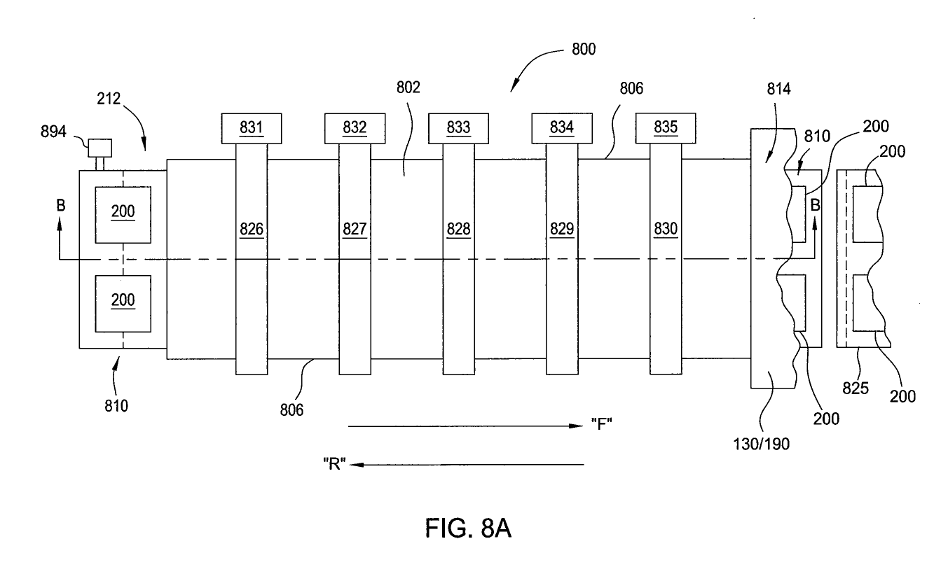

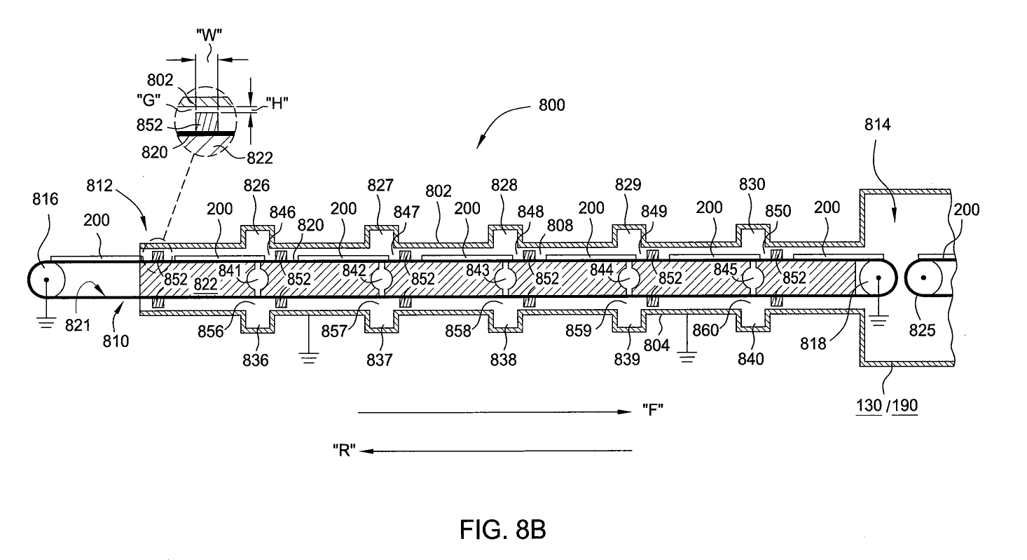

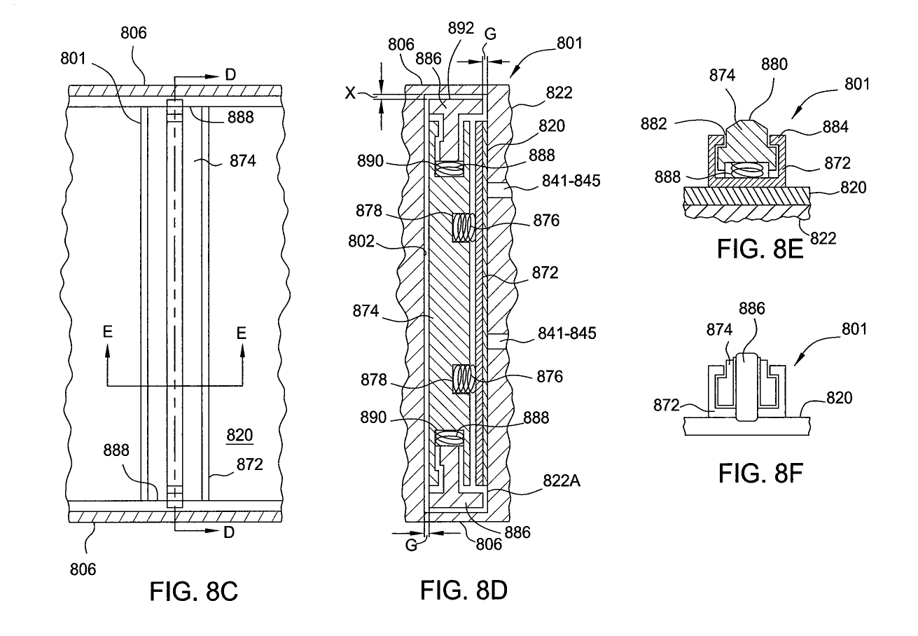

FIG. 8A is a schematic plan view of a dynamic load lock chamber 800 according to one embodiment of the present invention. FIG. 8B is a schematic, cross-sectional view of the dynamic load lock chamber 800 shown in FIG. 8B taken along section line B-B. The dynamic load lock chamber 800 may correspond to the first dynamic load lock chamber 120, when configured to transport the substrates 201 in the forward direction “F” (e.g., from atmospheric pressure to vacuum), and it may correspond to the second dynamic load lock chamber 192, when configured to transport the substrates 201 in a reverse direction “R” (e.g., from vacuum to atmospheric pressure), as shown in FIGS. 8A and 8B.

Regardless of the direction in which the substrates 201 are transferred, a function of the dynamic load lock chamber 800 is to continuously transport the substrates 201 to the processing chamber 130 or from the processing chamber 190, while eliminating the flow of gases from an atmospheric pressure side of the dynamic load lock chamber 800 to the vacuum conditions inside the processing chambers 130, 190. To accomplish this desired function, the internal volume of the dynamic load lock chamber 800 is configured into a plurality of discrete volumes that are moveable along a linear path between the atmospheric side of the dynamic load lock chamber 800 and the vacuum conditions inside the one or more processing chambers 130, 190 as the substrates, disposed within these discrete volumes, are transported therebetween. As subsequently described below, the pressure in the discrete volumes are separately reduced to staged levels as they are transferred along the substrate transfer path during the substrate transfer process. The division between the discrete volumes is provided by separation mechanisms disposed on a continuously moving, linear substrate transport belt, which transports substrates between the atmospheric side of the dynamic load lock chamber 800 and the one or more processing chambers 130, 190.

The dynamic load lock chamber 800 includes a top wall 802, a bottom wall 804, and side walls 806 enclosing a staged load lock region 808. The walls 802, 804, and 806 may be fabricated from typical material used for substrate processing chambers, such as stainless steel or aluminum. A linear conveying mechanism 810 extends through the staged load lock region 808 from an atmospheric pressure side 812 of the dynamic load lock chamber 200 to a processing pressure side 814 of the dynamic load lock chamber 200. The linear conveying mechanism 810 includes one or more rollers 816 positioned on the atmospheric pressure side 812 and one or more rollers 818 positioned on the processing pressure side of the dynamic load lock chamber 800. The one or more rollers 816, 818 support and drive a continuous transport belt 820 of material configured to support and transport the substrates 201 through the load lock chamber 800. The rollers 816, 818 may be driven by a mechanical drive 894 (FIG. 8A), such as a motor/chain drive (not shown), and may be configured to transport the transport belt at a linear speed of up to about 10 m/min. The mechanical drive 894 may be an electric motor (e.g., AC or DC servo motor) that is geared to provide a desired transport belt 820 velocity during processing. The transport belt 820 may be made of a stainless steel, aluminum, or polymeric material. One or more support plates 822 may extend between the side walls 806 to support an interior surface of the transport belt 820. The interior surface of the transport belt 820 is generally supported by a surface 822A (FIG. 8D) of the one or more support plates 822.

The upper wall 802 of the load lock chamber 800 includes a plurality of pockets 826, 827, 828, 829, and 830 formed therein that are fluidly coupled to a plurality of actuators 831, 832, 833, 834, and 835, respectively. Each of the pockets 826-830 is further in fluid communication with a respective discrete region of the staged load lock region 808. For example, the pocket 826 is in fluid communication with a region 846. The pocket 827 is in fluid communication with a region 847. The pocket 828 is in fluid communication with a region 848. The pocket 829 is in fluid communication with a region 849, and the pocket 830 is in fluid communication with a region 850.

The lower wall 804 includes a plurality of corresponding pockets 836, 837, 838, 839, and 840 formed therein and coupled to the plurality of actuators 831, 832, 833, 834, and 835, respectively. Each of the pockets 836-840 is further in fluid combination with a respective discrete region of the staged load lock region 808. For example, the pocket 836 is in fluid communication with a region 856. The pocket 837 is in fluid communication with a region 857. The pocket 838 is in fluid communication with a region 858. The pocket 839 is in fluid communication with a region 859, and the pocket 840 is in fluid communication with a region 860.

In addition, the one or more support plates 822 may also include corresponding pockets 841, 842, 843, 844, and 845 formed therein that are coupled to the plurality of actuators 831, 832, 833, 834, and 835, respectively. Each of the pockets 841-845 are fluidly coupled to respective discrete regions of the staged load lock region 808. For example, the pocket 841 is in fluid communication with respective regions 846 and 856. The pocket 842 is in fluid communication with respective regions 847 and 857. The pocket 843 is in fluid communication with respective regions 848 and 858. The pocket 844 is in fluid communication with respective regions 849 and 859, and the pocket 845 is in fluid communication with respective regions 850 and 860.

In one embodiment, the plurality of actuators 831-835 includes a plurality of pumps set to progressively reduce the pressure in the dynamic load lock chamber 800 from the atmospheric pressure side 812 to the processing pressure side 814. In this embodiment, each of the pumps are configured to reduce a volume within the staged load lock region 808 corresponding to the pockets to which the pump is coupled. For example, the actuator 831 may be configured to reduce the pressure in respective regions 846 and 856 to a first pressure (e.g., 480-600 mbar), which is less than atmospheric pressure. The actuator 832 may be configured to reduce the pressure in respective regions 847 and 857 to a second pressure (e.g., 100-300 mbar), which less that the first pressure. The actuator 833 may be configured to reduce the pressure in respective regions 848 and 858 to a third pressure (e.g., 10-100 mbar), which is less than the second pressure. The actuator 834 may be configured to reduce the pressure in respective regions 849 and 859 to a fourth pressure (10⁻²-1 mbar), which is less than the third pressure, and the actuator 835 may be configured to reduce the pressure in respective regions 850 and 860 to a fifth pressure (10⁻⁴-10⁻² mbar), which is less than the fourth pressure and which may be greater than the pressure within the one or more processing chambers 130, 190 (e.g., 10⁻⁵ mbar). In one configuration, the plurality of actuators 831-835 are replaced by a single actuator that is fluidly coupled to each of the pockets 826-830 and 836-845, wherein the single actuator is separately connected and valved to control the pressure within and/or gas flow received from each of these pockets. In another embodiment, the actuator 831 may include a compressor configured to inject clean dry air (CDA) or alternatively an inert gas, such as argon or nitrogen, into the respective regions 846 and 856 at a first pressure slightly above atmospheric pressure (e.g., 15-100 mbar above atmospheric pressure). Such an overpressure condition within the regions 846 and 856 assures that contaminants from the atmospheric pressure side 812 are not introduced into the dynamic load lock chamber 800 and consequently the one or more processing chambers 130, 190.

In this embodiment, the actuators 832-835 include a plurality of pumps set to progressively reduce the pressure from the respective regions 846 and 856 to the processing pressure side 814 of the dynamic load lock chamber 800. For example, the actuator 832 may be configured to reduce the pressure in respective regions 847 and 857 to a second pressure (e.g., 300-600 mbar), which is less that the first pressure. The actuator 833 may be configured to reduce the pressure in respective regions 848 and 858 to a third pressure (e.g., 50-200 mbar), which is less than the second pressure. The actuator 834 may be configured to reduce the pressure in respective regions 849 and 859 to a fourth pressure (e.g., 1-50 mbar), which is less than the third pressure, and the actuator 835 may be configured to reduce the pressure in respective regions 850 and 860 to a fifth pressure (e.g., 10⁻²-1 mbar), which is less than the fourth pressure and which may be greater than the pressure within the one or more processing chambers 130, 190 (e.g., 10⁻⁵ mbar).

Although the actuators 831-835 are configured for increased pressure reduction from the atmospheric pressure side 812 to the processing pressure side 814 of the dynamic load lock chamber 800, a difficulty remains in maintaining some separation between adjacent regions within the staged load lock region 808 because each of the adjacent regions are in fluid communication with one another. In order to assure such separation between adjacent regions and provide a semi-enclosed region in which to expose individual or groups of substrates 201 to each pressure stage as it passes through the dynamic load lock chamber 800, a plurality of separation mechanisms 852 are attached to the transport belt 820. The separation mechanisms 852 may be spaced along the surface of the transport belt such that one or more substrates 201 (e.g., an array of two or more substrates 201) may be positioned between each separation mechanism 852.

In addition, the separation mechanisms 852 may be positioned so that a small gap “G” is provided between surfaces of each separation mechanism 852, which are coupled to a portion of the transport belt 820, and the top wall 802, side wall 806 and/or bottom wall 804 of the dynamic load lock chamber 800. The gap “G” may have height “H” between 0 and 3 mm, preferably between 0 and 0.2 mm, and a width “W” between 1 and 30 mm. In one configuration, the gap “G” defined between each separation mechanism 852 and the top wall 802, side wall 806 and/or bottom wall 804 of the dynamic load lock chamber 800 provides a controlled fixed gap through which the gas disposed in an adjacent higher pressure region (e.g., region 846) will pass as it leaks into an adjacent lower pressure region (e.g., region 847) as both are moved in a desired direction as the transport belt 820 is moved by the mechanical drive 894. The separation mechanisms 852 are used to form a known and repeatable space through which gas will flow as the separation mechanisms 852 and substrates are moved, for example, from the atmospheric pressure side 812 to the processing pressure side 814 of the first dynamic load lock chamber 800. The pumping capacity of each of the actuators 831-835 and the size of gap “G” formed between the walls 802, 804, 806 and the separation mechanisms 852 are selected so that a controlled flow of gas, or “gas leak”, is created between the separation mechanisms 852 and the walls 802, 804, 806, during the substrate transferring process, so that the pressure over the substrates 201 is continually reduced as they are transferred from one end of the dynamic load lock chamber 800 to the other in the forward “F” direction (i.e., first dynamic load lock chamber 120), or vice versa in the reverse direction “R” (i.e., second dynamic load lock chamber 192). In one embodiment, at least a portion of one or more of the separation mechanisms 852 are configured to contact one or more of the walls 802, 804, 806 to minimize the gap through which gas can flow from the higher pressure region on one side of the separation mechanism to the other side of the separation mechanism.

Further, since a back side 821 of the substrate transport belt 820 may provide a “gas leak” path between adjacent regions of the dynamic load lock chamber 800, the pockets 841-845 disposed within the one or more support plates 822 are configured to assure that the pressure conditions between the back side 821 of the transport belt 820 and the one or more support plates 822 is maintained at the same pressure as the remainder of the respective regions in which it is in fluid communication. For example, the pocket 841 is configured to assure that the back side 821 of the transport belt 820 within the region 846 is maintained at the same pressure as the region 846.

FIG. 8C is a partial plan view of a separation mechanism 801 attached to a transport belt 820 according to one embodiment. FIG. 8D is a cross-sectional view of the separation mechanism taken along lines D-D. FIG. 8E is a cross-sectional view of the separation mechanism 801 taken along line E-E. FIG. 8F is a schematic end view of the separation mechanism 801 from FIG. 8C.

As illustrated, the separation mechanism 801 is a linear member disposed across the width of the transport belt 820. The separation mechanism 801 includes a housing member 872 attached to the transport belt 820 using one or more suitable fasteners, such as screws, bolts, adhesives, or the like. The housing member 872 may be fabricated from a material typically used in substrate processing environments, such as stainless steel, aluminum, or a suitable polymeric material. A vane 874 is disposed within the housing member 872. The vane 874 may be manufactured from a suitable polymer material, such as a self lubricating polymer to provide low sliding resistance and possibility of contamination when the vane 872 is in contact with the top wall 802 or bottom wall 804. One example of a polymer material that may be used in the vane 874 is ORIGINAL MATERIAL “S”® 8000 manufactured by Murtfeldt Kunststoffe GmbH & Co. KG of Dortmund, Germany. Alternatively, the vane 874 may be manufactured of other materials, such as a metallic material (e.g., stainless steel, aluminum) or graphite.

The vane 874 is spring-loaded within the housing member 872 using spring members 876. The spring members 876 may be mechanical springs. Alternatively, the spring members 876 may include magnetic, hydraulic, or pneumatic actuators. Optionally, the spring members 876 may include gravity activated actuation, such as a pivot or rocker which may be configured to an extended position under normal circumstances and pivot to a retracted position if contacted. The spring members 876 may be disposed within a slot 878 and contacting the housing member 872 such that an upper portion 880 of the vane 874 extends through an opening 882 in the housing member 872 and above an upper surface 884 of the housing member 872. As such, the vane 874 provides the gap “G” between the separation mechanism 801 and the top wall 802 and/or the bottom wall 804. Preferably the vane 874 is in contact with the top wall 802 and/or bottom wall 804 as the substrates are transported through the dynamic load lock chamber 800 to minimize the gas leak between discrete regions of the chamber 800. In addition, since the vane 874 is spring loaded, less friction between the separation mechanism 801 and top wall 802 or bottom wall 804 is provided during contact. Consequently, the chances of contamination within the dynamic load lock chamber 800 are significantly reduced.

The separation mechanism 801 further includes an end member 886 disposed at each end of the separation mechanism 801. Each end member 886 is spring-loaded within the vane 874 using spring members 888. The spring members 888 may be disposed within a slot 890 and contacting the vane 874 such that an outer portion 892 of the end member 886 extends outside of the outer surface of the vane 874. As such, each end member 886 provides a small gap (e.g., same dimensions as the gap “G”) between the separation mechanism 801 and the respective side wall 806. Preferably, each end member 886 is in contact with the respective side wall 806 as the substrates are transported through the dynamic load lock chamber 800 to minimize the gas leak between discrete regions of the chamber 800. In addition, since the end members 886 are spring loaded, less friction between the separation mechanism 801 and the side walls 806 is provided during contact. Further, the spring members 888 may be manufactured from the same material as the vane 874, such as a self-lubricating polymer. Consequently, the chances of contamination within the dynamic load lock chamber 801 are significantly reduced. The end member 874 is generally configured so that a desirable gap (e.g., gap “G”) is formed between its exterior surfaces and the surface 822A of the support plates 822 and the inner surfaces of side wall 806 and top wall 802. As described above, the gap “G” is sufficiently small to minimize “gas leak” between adjacent regions of the dynamic load lock chamber 800 as the substrates 201 are transported therethrough.

### Processing System Configuration Examples

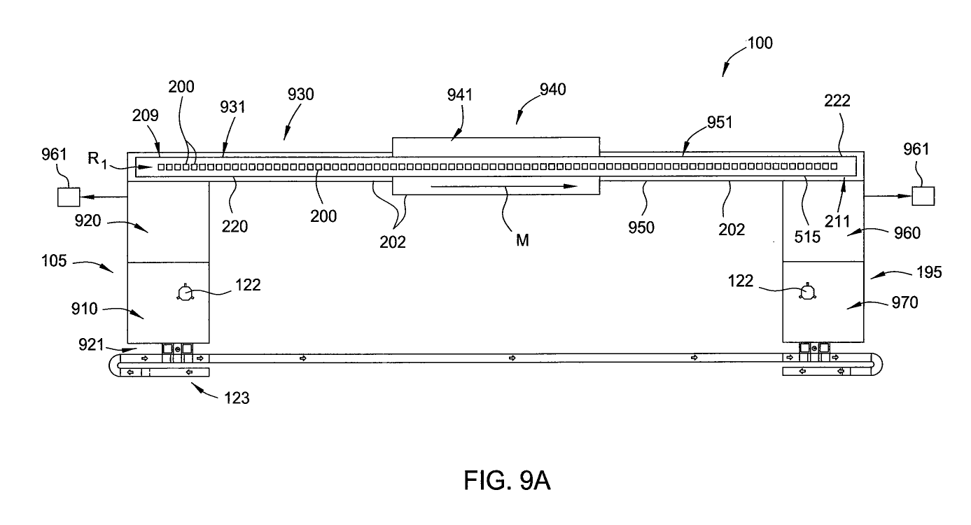

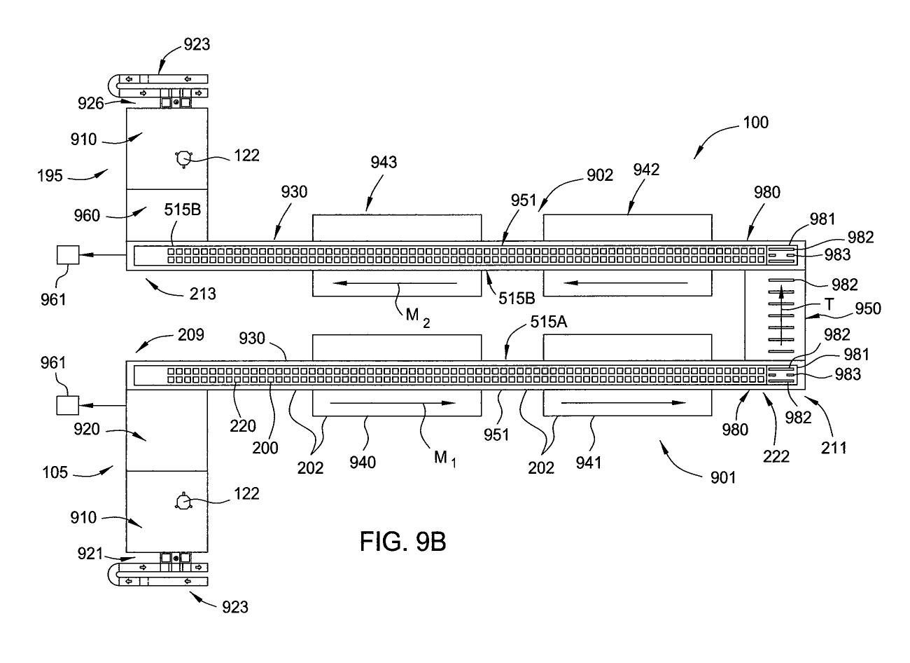

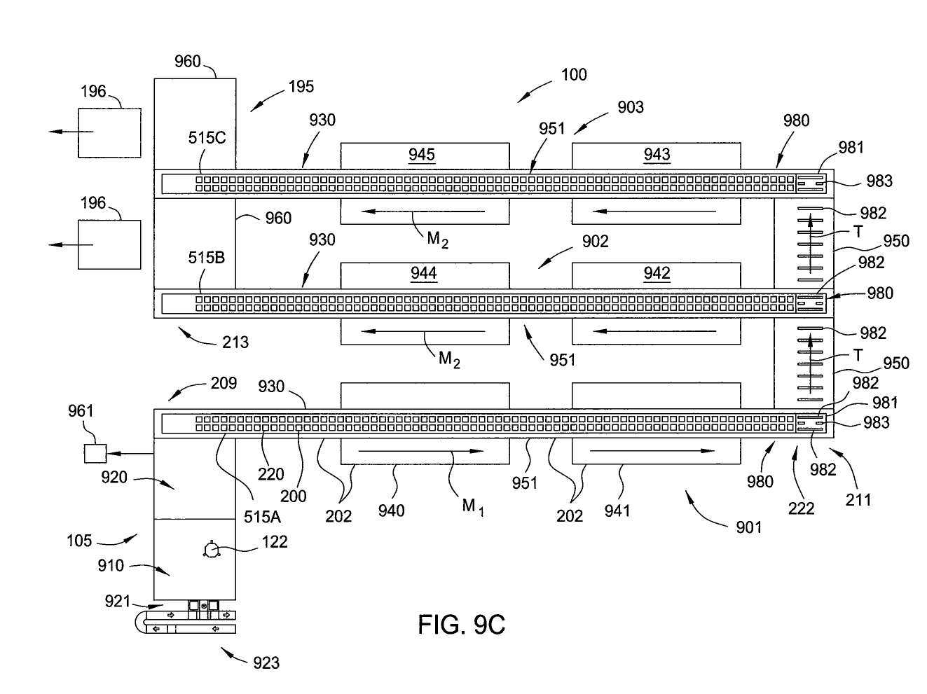

FIGS. 9A-9C illustrate further examples of different embodiments of the processing system 100. One will note that processing chambers 940-945 illustrated the FIGS. 9A-9C may comprise one of the processing chambers, such as a processing chamber 400, 500, 600, 700 that are discussed herein. In general, the processing systems 100 illustrated in FIGS. 9A-9C will include a substrate receiving chamber 105, one or more processing chambers 940-945 and a substrate unload chamber 195. While FIG. 9A illustrates a processing system that is adapted to process a single row (R₁) of substrates, and FIGS. 9B-9C each illustrate processing systems that are adapted to process two rows (R₁-R₂) of substrates, these configurations are not intended to be limiting as to the scope of the invention described herein, since a greater or fewer number rows of substrates may be desirably processed in any of these processing system 100 configurations shown in these figures, or any of the figures shown above.

FIG. 9A illustrates an embodiment of the substrate processing system 100 that allows for the simplified transfer of the substrate stack boxes or cassettes between the input and output portions of the processing system 100. In this configuration, cassettes or stack boxes that are emptied by the automation components in the substrate receiving chamber 105 are then transferred to the substrate unload chamber 195, where the emptied stack boxes or cassettes can then receive the substrates that were processed in the system. In one configuration, the processing system 100 may include a substrate receiving chamber 105, pre-processing chamber 930, at least one processing chamber, such as a first processing chamber 940 (e.g., processing chamber 500, 700), and at least one support chamber (e.g., chamber 400, 600), and a substrate unload chamber 195. During processing the substrate receiving chamber 105 is configured to receive substrates (e.g., substrates 200) from a substrate transport interface 921 and position them on a portion of the substrate automation system 515 so that they can be transferred through the various processing chambers found in the processing system 100. The substrate transfer interface 921 will generally receive substrates from one or more modular substrate conveyors 123 that are configured to receive cassettes or stack boxes containing multiple substrates. In one configuration, the actuator assembly 122 disposed in the inlet portion 910 of the substrate receiving chamber 105 is configured to transfer substrates from the transport interface 921, which is at atmospheric pressure, into a staging region 920 that is at an intermediate vacuum pressure, due to the use of the vacuum pump 961. The actuator assembly 122 may then position the transfer substrates onto a portion of the substrate automation system 515. The substrates that are positioned on the substrate automation system 515 are then moved through the processing chambers in a direction “M” until they reach the second end 211 of the processing system 100. Once at the second end 211, the substrates are then removed from the substrate automation system 515 by use of the actuator assembly 122 found in the outlet portion 970 of the substrate unloading chamber 195. The actuator assembly 122 disposed in the substrate unloading chamber 195 is generally configured to transfer substrates from the substrate automation system 515 through a staging region 960, which is at an intermediate vacuum pressure by use of a vacuum pump 961, and then onto the transport interface 926, which is disposed in a region that is at atmospheric pressure. The actuator assemblies 122 disposed in the substrate receiving chamber 105 and substrate unloading chamber 195 may each comprise one or more roller conveyors that are configured to support and transfer the substrates as they are moved between the substrate automation system 515 and the interfaces 921, 926. While the substrates 200 are being processed within the processing chambers within the processing system 100, the substrate stack boxes or cassettes that were emptied in a substrate receiving chamber 105 can be delivered to the substrate unload chamber 195 by use of the one or more modular substrate conveyors 923 that are adapted to transport these elements by use of a conventional belt, rollers, linear motor or other similar conveyance system. While FIG. 9A only illustrates a single processing chamber that is adapted to process a single row (R₁) of substrates, this configuration is not intended to be limiting as to the scope of the embodiments of the invention described herein, since the processing system 100 illustrated in FIG. 9A may contain one or more processing chambers and/or support chambers without deviating from the basic scope of the invention described herein.

FIG. 9B illustrates an embodiment of the substrate processing system 100 that allows the substrates to be placed within and removed from the processing system 100 from the same end, thus making it easier to connect the processing system 100 to other up-stream and down-stream processing systems found in the solar cell production fab. In one configuration, the processing system 100 may include a substrate receiving chamber 105, at least one processing chamber, such as a first processing chamber 940-943 (e.g., chamber 500, 700), and at least one support chamber 930, 950, 951 (e.g., chamber 400, 600), and a substrate unload chamber 195. In one configuration the chamber 950 comprises a substrate reorienting device, similar to the one illustrated in FIG. 7A, discussed above.

During processing the substrate receiving chamber 105 is configured to receive substrates (e.g., substrates 200) from a substrate transport interface 921 and position them on a portion of the substrate automation system 515 so that they can be transferred through the various processing chambers found in the first processing region 901 of the processing system 100. One will note that the process of transferring substrates from the substrate transfer interface 921 to a first portion of the substrate automation system 515, hereafter first substrate automation system 515A, and from a second portion of a substrate automation system 515, hereafter second substrate automation system 515B, to the substrate transfer interface 926 in the configuration of the processing system 100 shown in FIG. 9B is similar to the discussion above and thus will not be re-recited herein. Once the substrates are positioned on the first substrate automation system 515A by use of an automation device (e.g., actuator assembly 122) they are then moved in a direction “M₁” through and processed within the processing chambers disposed in the first processing region 901 of the processing system 100 until they reach the second end 211. Once at the second end 211, the substrates are then transferred from the first substrate automation system 515A in the first processing region 901 to the second substrate automation system 515B disposed in the second processing region 902 (FIG. 7B) by use of one or more actuator assemblies 981. The substrates that are positioned on the second substrate automation system 515B are then moved in a direction “M₂” through and processed within the processing chambers disposed in the second processing region 902 until they reach the third end 213 of the processing system 100. The processed substrates are then removed from the substrate automation system 515B by use of the actuator assembly 122 found in the outlet portion 970 of the substrate unloading chamber 195.

The actuator assemblies 981 are generally configured to receive substrates from an end of the first portion of the first substrate automation system 515A and then serially transfer the substrates that reach the end of the first portion of the first substrate automation system 515A to a second substrate automation system 515B. An actuator assembly 981 may comprise a first set of motorized rollers, or first rollers 983, and a second set of motorized rollers, or second rollers 982, that are positioned transverse to each other to allow rapid movement of the substrates from or to an adjacently positioned substrate automation system. In one example, as shown in FIGS. 9B and 9C, at least one actuator assembly 981 is configured to receive substrates from a first substrate automation system 515A disposed in a first processing region 901 by receiving the substrates 200 from an exit conveyor 222 and positioning them on the first rollers 983. Once the substrates have been received and are supported by the first rollers 983, the second rollers 982 are actuated relative to the first rollers 983, so that the substrates are now supported on the second rollers 982. Then once the substrates are supported by the second rollers 982 they are actuated to cause them to move the substrates 200 in a direction orthogonal to the direction from which the substrates were received by the first rollers 983 from the substrate automation assembly (e.g., direction “T”). Next, the actuator assemblies 981 can transfer the substrates to a second actuator assembly 981 so that the substrates can be positioned on a second portion of a substrate automation assembly, or second substrate automation system 515B. The substrates can be positioned on the second substrate automation system 515B by using one or more sets of the motorized rollers 982, 983. One will note that the process of loading the substrates 200 onto the second substrate automation system 515B is similar to the process of unloading substrates from the first substrate automation system 515A, except that the process steps are done in reverse. In this substrate transferring configuration, the often fragile solar cell substrates are less likely to break or crack, due to loads applied during the transferring process, since they are at least partially supported by a plurality of rollers at all times.

In one configuration of the processing system 100, which is similar to the configuration shown in FIG. 9B, the substrate receiving chamber 105 and the substrate unload chamber 195 are coupled together so that the substrate receiving chamber 105 can receive a cassette containing multiple substrates (e.g., substrates 200) from a substrate transport interface 921, unload the substrates from the cassette to the first substrate automation system 515A and then transfer the received and unloaded cassette directly to the substrate unload chamber 195, where the processed substrates can then be reloaded into the waiting cassette, and then the cassette can be removed from the processing system. In one embodiment, the substrate receiving chamber 105 and the substrate unload chamber 195 are coupled together and maintained at a pressure below atmospheric pressure by use of a vacuum pump (not shown), so that the cassette can remain under a vacuum pressure from the time that it is received by the substrate receiving chamber 105 until it exits the substrate unload chamber 195. The substrate receiving chamber 105 and substrate unload chamber 195 may each contain a load-lock region that is configured to receive a cassette and also be pump down and vented between a vacuum and an atmospheric pressure. A conveyor or robotic actuator may be used to transfer the cassette between the substrate receiving chamber 105 and the substrate unload chamber 195 while the environment surrounding the cassette is maintained at a vacuum pressure.

FIG. 9C illustrates an embodiment of the substrate processing system 100 that allows in-situ processing of a substrate using processes that have different processing times to be integrated together to provide a high substrate throughput. In one configuration, the processing system 100 may include one or more substrate receiving chambers 105, at least one processing chamber, such as a first processing chamber 940-945, at least one support chambers 930, 951 (e.g., chamber 400, 700), and one or more substrate unload chambers 195. Thus, in one configuration, as shown in FIG. 9C, the processing system 100 contains two processing chambers 940, 941 in a first processing region 901, two processing chambers 942, 944 in a second processing region 902, and two processing chambers 943, 945 in a third processing region 903, of a processing system 100. In the configuration as shown, the processes performed in the first processing region 901 of the processing system 100 will allow the first portion of the substrate automation assembly, or first substrate automation system 515A to transfer and process the substrates at a high speed, while the processes performed in the second and third processing regions 902, 903 will only allow the second and third substrate automation assemblies 515B, 515C, respectively, to transfer substrates a second speed that is lower than the first high speed. In one example, the first substrate automation assembly 515A is adapted to transfer substrates at a speed of about 5 meters/minute through the processing chambers 940, 940 and support chambers 930, 951, while the second and third portions of the substrate automation assembly 515B, 515C are adapted to transfer the substrates at a speed of about 2.5 meters/minute through the processing chambers and support chambers found in processing regions 902 and 903.

During processing the substrate receiving chamber 105 is configured to receive substrates (e.g., substrates 200) from a substrate transport interface 921 and position them on a first substrate automation system 515A so that they can be transferred through the various processing chambers found in the first processing region 901 of the processing system 100. Once the substrates have been received and processed by the processing chambers found in the first processing region 901 they can be processed by the components in the chamber 950 and/or selectively transferred to the second and third processing regions 902, 903, respectively, by use of the one or more actuator assemblies 981 disposed at the second end 222 of the processing system 100, as discussed above. The substrates that are received by either the second substrate automation system 515B or the third substrate automation system 515C can then be transferred through and processed within the various processing chambers found in the either second or third processing regions 902, 903 of the processing system 100. In one example, the passivation/ARC layer stack 320 (FIG. 3) is formed on the substrates 200 transferred through the first processing region 901 using a first automation system 515A, which is configured to transfer at least one row of substrates (R₁) at a first transfer speed, and a rear surface passivation layer stack 340 is formed on the substrates 200 transferred through the either the second or third processing regions 902, 903 using the second and third automation systems 515B, 515C, which are each configured to transfer at least one row of substrates (R₁) at a second transfer speed. In one example, the first automation system 515A may be configured to transfer two rows of substrates at a first transfer speed and the second and third automation systems 515B, 515C are each configured to transfer two rows of substrates at a second transfer speed, wherein the first transfer speed is double the second transfer speed. In one example, the first automation system 515A may be configured to transfer a single row of substrates at a first transfer speed and the second and third automation systems 515B, 515C are each configured to transfer two rows of substrates at a second transfer speed, wherein the first transfer speed is four times faster than the second transfer speed.

Referring to FIG. 9C, once at the third end 213, the substrates are then removed from the substrate automation system 515 by use of one or more actuator assemblies 122 found in the staging regions 960 of the substrate unloading chamber 195. In one embodiment, the one or more actuator assemblies 122 disposed in the substrate unloading chamber 195 are generally configured to transfer substrates 200 from the substrate automation systems 515B, 515C through the staging regions 960, which is at an intermediate vacuum pressure by use of a vacuum pump (not shown), and then onto the transport interface of one or more subsequent processing systems 196, which is disposed in a region that is at atmospheric pressure. The actuator assemblies 122 disposed in the substrate unloading chamber 195 may each comprise one or more roller conveyors that are configured to support and transfer the substrates as they are moved between the substrate automation system and the interface 926. In some configurations, the one or more subsequent processing systems 196 may include one or more substrate conveyors that are adapted to deliver the processed substrates to one or more metallization chambers, such as a screen printing chamber available from Applied Materials Italia S.r.l. (e.g., Soft Line™ system) so that a metal containing paste can be deposited on the surface of the substrates to form metal contacts with various regions of the substrates. An example of screen printing system that may be coupled with the substrate unloading chamber 195 is further described in U.S. patent publication number 2009/0305441, filed Apr. 6, 2009, which is incorporated by reference in its entirety.

### Processing Sequence Example

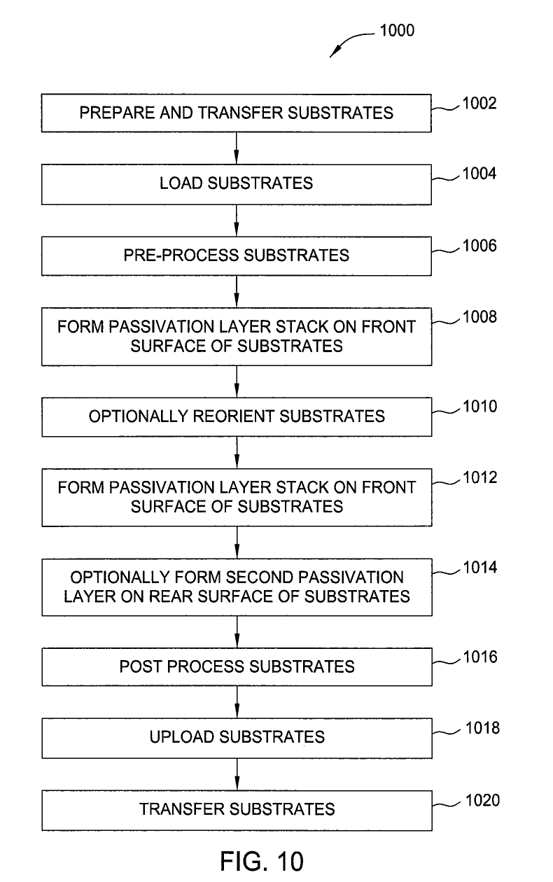

FIG. 10 is a block diagram illustrating a processing sequence performed on a plurality of substrates in a processing system, in accordance with one embodiment of the present invention described herein. In one embodiment, the processing sequence 1000 may be performed in a processing system that is similar to the processing system 100 illustrated in FIGS. 2B-2C. It is noted that the processing sequence depicted in FIG. 8 is only used as an example of a process flow that may be used to manufacture solar cell devices. Additionally steps may be added in between any of the steps depicted in FIG. 10 as needed for different device structure requirements. Similarly, one or more steps depicted herein may also be eliminated as needed.

In one embodiment, the processing sequence 1000 performed on the plurality of substrates processed in the processing system 100, starts at step 1002 in which a plurality of substrates 200 are prepared and delivered to the processing system 100. As noted above, the processed substrates may be delivered to the substrate transport interface 121 via a modular conveyor 123. In one example, the preprocessed substrates include substrates that have a p-type doped base region 301 and n-type doped emitter region 302 formed in the substrates 200, the substrates 200 have been textured and chemically cleaned so that the substrates can be further processed in a vacuum environment to form a passivation/ARC layer stack 320 on a textured front surface 305 of the substrates 200 and a rear surface passivation layer stack 340 on the rear surface 306 of the substrates 200 in the processing system 100. The cleaning processes performed on the substrates 200 prior to insertion into the processing system 100 are generally used to remove any undesirable materials that could affect the passivation layer properties and/or contaminate the processing region 210 of the processing system 100. The substrates 200 may be cleaned using a wet cleaning process in which a cleaning solution, such as a HF-last type cleaning solution, ozonated water cleaning solution, hydrofluoric acid (HF) and hydrogen peroxide (H₂O₂) solution, or other suitable cleaning solution. In some configurations, the substrates 200 may be a single crystal or multicrystalline silicon substrate, silicon containing substrate, doped silicon containing substrate, or other suitable substrates. In the embodiment depicted herein, the substrates 200 are p-type crystalline silicon (c-Si) substrates, as discussed above in conjunction with FIG. 3.

Next, at step 1004, the substrate receiving chamber 105 receives the substrates from the one or more modular substrate conveyors 123 that are configured to receive cassettes or stack boxes containing multiple substrates. In one configuration, an actuator assembly 122 (e.g., conveyor, robot) disposed in a substrate receiving chamber 105 is configured to transfer substrates from the modular substrate conveyors 123, which is at atmospheric pressure, into the dynamic load lock chamber 120, so that they can then be moved through the processing chambers coupled to the processing region 210 in the processing system 100. The actuator assembly 122 can be used to serially transfer the substrates to a surface of the conveyor 220 as the surface is translated in a first direction (e.g., ⁺X-direction) so that at least one row (e.g., R₁-R₂) of substrates are formed and aligned along the first direction.

At step 1006, the substrates are transferred through one or more pre-processing chambers, such as processing chambers 130 (FIG. 2B) that contains the processing chamber 400 (FIG. 4) which are discussed above, to prepare the substrates for the deposition processes performed in subsequent processing chambers. In one configuration, the pre-processing chambers are configured to deliver energy, such as radiant heat to the substrates as they are transferred through the portion of the processing region 210 found in the preprocessing chamber by the substrate automation assembly 515. In one example, the pre-processing chamber components are configured to heat the substrates to a temperature between about 100° C. and 450° C. as they are transferred through the processing region of the of the pre-processing chamber. In some configurations, heating, dry etching, doping or other similar processes may be performed on the plurality of substrates as they are serially transferred through the processing region of the pre-processing chamber.

At step 1008, one or more layers of a passivation/ARC layer stack 320 are formed on the front surface 305 of the substrates 200 using two or more deposition sources (e.g., deposition sources 560A, 560B, 560C, 560D), which are disposed in the portion of the processing region 210 disposed in a processing chamber 140, as the substrates are transferred relative to the deposition sources 560A-560D by use of the substrate automation system 515. In one configuration, the processing chamber 140 may comprise a processing chamber 500, which is illustrated in FIGS. 5A-5D. In one example, the passivation/ARC layer stack 320 may comprise two or more antireflection/passivation layers, which may comprise silicon oxide and/or silicon nitride. In one example, during processing in the processing chamber a first gas source 528 and a second gas source 529 are configured to deliver one or more precursor gases or carrier gases to the surface of the substrates 200 by use of the deposition sources 560A-560D disposed in the processing chamber 140. The first gas source 528 and the second gas source 529 may be adapted to deliver silane (SiH₄), ammonia (NH₃), nitrogen (N₂), and hydrogen (H₂) to the processing region 525 formed over the substrates 200. The power source 530 may be adapted to deliver RF energy (e.g., 100 W to 4 kW at up to 13.56 MHz) to the process gasses disposed in the processing region 525 over the substrates 200. In one embodiment, the first deposition source 560A and second source 560B are configured to form a first layer 321, of the passivation/ARC layer stack 320, by providing nitrogen (N₂) and silane (SiH₄) at a ratio (N₂/SiH₄) of about 1:1 or less while the substrates are maintained at a temperature of between about 300-400° C. by use of the heating elements 584, RF power of about 4000 Watts is provided by a power source 530 and processing pressure of about 10 mTorr is maintained to form a silicon nitride (SiN) layer that is between about 50 Angstroms (Å) and about 350 Å thick on the surface of the substrate. The third deposition source 560C and fourth source 560D may also be configured to form a second layer 322 of the passivation/ARC layer stack 320 on the first layer 321, by providing nitrogen (N₂) and silane (SiH₄) at a ratio (N₂/SiH₄) of about 1:1 or greater and ammonia (NH₃) at a ratio to silane (NH₃/SiH₄) of about 1:1 while the substrates are maintained at a temperature of between about 300-400° C. by use of the heating elements 584, RF power of about 4000 Watts is provided by a power source 530 and processing pressure of about 10 mTorr is maintained to form a silicon nitride (SiN) layer that is between about 400 Angstroms (Å) and about 700 Å thick on the surface of the substrate.

At step 1010, optionally a substrate is reoriented so that a deposition process can be performed on the rear surface 306 of the substrate, which is on a side of the substrates 200 that are opposite to the front surface 305. The process of reorienting the substrates is generally similar to the processes described above in conjunction with FIGS. 7A-7B, which is discussed above. In one configuration of the processing sequence 1000, the substrates 200 are all reoriented in groups (e.g., at least one column of substrates (e.g., two substrates in a two row (R₁-R₂) configuration)). In one example, to allow the substrates to be reoriented, the substrates disposed on the substrate automation system 515 are transferred in groups into a reorienting device, such as the reorienting device 705 illustrated in FIG. 7A, and then all of substrates disposed on the substrate automation system 515 are momentarily stopped so that the reorienting device can “flip” the orientation of the substrates from a facing-up configuration to a facing-down configuration. However, it is generally desirable to keep the various conveyors 220, 221, 222 in the substrate automation system 515 moving at a continuous speed to achieve the high substrate throughput requirements for solar cell manufacturing.

At steps 1012 and 1014, a rear surface passivation layer stack 340 is deposited on the second surface 306 (e.g., back surface) of the substrates 200. The rear surface passivation layer stack 340 may be a dielectric layer providing good interface properties that reduce the recombination losses in the formed solar cell device. In one embodiment, the rear surface passivation layer stack 340 may be fabricated from a dielectric material selected from a group consisting of silicon nitride (Si₃N₄), silicon nitride hydride (SixNy:H), silicon oxide, silicon oxynitride, a composite film of silicon oxide and silicon nitride, an aluminum oxide layer, a tantalum oxide layer, a titanium oxide layer, or any other suitable materials. In one configuration, the rear surface passivation layer stack 340 comprises a first rear surface layer 341 that comprises aluminum oxide layer (Al₂O₃). The aluminum oxide layer (Al₂O₃) may be formed by using two or more deposition sources (e.g., deposition sources 560A, 560B, 560C, 560D), which are disposed in the portion of the processing region 210 disposed in a processing chamber 160, as the substrates are transferred relative to the deposition sources 560A-560D by use of the substrate automation system 515. In one configuration, the processing chamber 160 may comprise a processing chamber 500, which is illustrated in FIGS. 5A-5D. In one example, during processing in the processing chamber a first gas source 528 and a second gas source 529 are configured to deliver one or more precursor gases or carrier gases to the surface of the substrates 200 by use of the deposition sources 560A-560D disposed in the processing chamber 160. The first gas source 528 and the second gas source 529 may be adapted to deliver trimethyl aluminum (TMA) and oxygen (O₂) to the processing region 525 formed over the substrates 200. The power source 530 is may be adapted to deliver RF energy (e.g., 100 W to 4 kW at up to 13.56 MHz) to the process gasses disposed in the processing region 525 over the substrates 200. In one embodiment of the process sequence 800, the first deposition source 560A and second source 560B are configured to form the first rear surface layer 341 by providing trimethyl aluminum (TMA) and oxygen (O₂) at a ratio (TMA/O₂) of about 1:3 while the substrates are maintained at a temperature of about 350° C. by use of the heating elements 584, RF power of about 4000 Watts is provided by a power source 530 and processing pressure of about 10 mTorr is maintained to form a aluminum oxide layer (Al₂O₃) layer that is between about 50 Angstroms (Å) and about 1200 Å thick on the surface of the substrates 200.

At step 1014, optionally the second rear surface layer 342 in the rear surface passivation layer stack 340 is deposited on the first rear surface layer 341 disposed on the second surface 306 (e.g., back surface) of the substrates 200. The second rear surface layer 342 may be a dielectric layer that provides good insulating properties, bulk passivation properties and act as a diffusion barrier for the subsequent metallization layers. At step 814, the second rear surface layer 342 is formed on the second surface 306 of the substrates 200 using two or more deposition sources (e.g., deposition sources 560A, 560B, 560C, 560D), which are disposed in the portion of the processing region 210 disposed in a processing chamber 180, as the substrates are transferred relative to the deposition sources 560A-560D by use of the substrate automation system 515. In one configuration, the processing chamber 180 may comprise a processing chamber 500, which is illustrated in FIGS. 5A-5D. In one example, the second rear surface layer 342 may comprise one or more passivation layers, which may comprise silicon nitride. In one example, during processing in the processing chamber a first gas source 528 and a second gas source 529 are configured to deliver one or more precursor gases or carrier gases to the surface of the substrates 200 by use of the deposition sources 560A-560D disposed in the processing chamber 180. The first gas source 528 and the second gas source 529 may be adapted to deliver silane (SiH₄), ammonia (NH₃), nitrogen (N₂), and hydrogen (H₂) to the processing region 525 formed over the substrates 200. The power source 530 is may be adapted to deliver RF energy (e.g., 100 W to 4 kW at up to 13.56 MHz) to the process gasses disposed in the processing region 525 over the substrates 200. In one embodiment, the first deposition source 560A, second source 560B, third source 560C and fourth source 560D in the processing chamber 180 are configured to form the second rear surface layer 342 on the first rear surface layer 341, by providing nitrogen (N₂) and silane (SiH₄) at a ratio (N₂/SiH₄) of about 1:1 or greater and ammonia (NH₃) at a ratio to silane (NH₃/SiH₄) of about 1:1 while the substrates are maintained at a temperature of between about 300-400° C. by use of the heating elements 584, RF power of about 4000 Watts is provided by a power source 530 and processing pressure of about 10 mTorr is maintained to form a silicon nitride (SiN) layer that is between about 400 Angstroms (Å) and about 700 Å thick on the surface of the substrate.

At step 1016, optionally the substrates 200 may be further processed in a processing chamber 190 prior to exiting the processing system 100. These post processing steps may be performed in one or more additional processing chambers as necessary to help reliably form a desirable solar cell device. In one embodiment, the post processing steps may include thermal processing (e.g., rapid thermal annealing, dopant drive-in steps) steps, laser ablation of regions of the substrates 200 to open vias in the passivation layers formed on either surface of the substrate to subsequently form back-surface-field (BSF) regions and electrical contacts to the surfaces of the substrates 200, and/or other deposition process steps, such as PVD or evaporation type contact layer deposition steps. In one example, an aluminum containing layer is deposited over the rear surface passivation layer stack 340 in the processing chamber 190 by an evaporation process to form metal contacts to portions of the rear surface 306 of the substrates 200. The contact regions created on the substrates 200 may have been formed by use of a laser ablation process that was performed after the rear surface passivation layer stack 340 was formed and before the aluminum layer deposition process steps.

Next, at steps 1018 and 1020, the substrate unload chamber 195 receives the substrates 200 from the dynamic load lock chamber 192 and transfers them to the one or more modular substrate conveyors 127 that are configured to contain and transfer the cassettes or stack boxes of processed substrates. In one configuration, an actuator assembly 122 (e.g., conveyor, robot) disposed in a substrate unload chamber 195 is configured to transfer substrates from the substrate automation system 515. The actuator assembly 122 then positions the substrates into a cassette disposed on the modular substrate conveyors 127 so that they can then be moved to other areas of the substrate production facility. At step 1020, the plurality of processed substrates 200 are then removed from the processing system 100 via the modular conveyor 127.

Embodiments of the present invention thus generally provide, a solar cell processing system that comprises a substrate automation system having one or more conveyors that are configured to transfer substrates serially through a processing region in a first direction, a first processing chamber having two or more first deposition sources disposed in the processing region, wherein each first deposition source is configured to separately deliver a processing gas to a surface of each of the substrates as the substrates are transferred through the processing region relative to the two or more first deposition sources, and a second processing chamber having two or more first deposition sources disposed in the processing region, wherein each second deposition source is configured to separately deliver a processing gas to the surface of each of the substrates as the substrates are transferred through the processing region relative to the two or more second deposition sources.

While the foregoing is directed to embodiments of the present invention, other and further embodiments of the invention may be devised without departing from the basic scope thereof, and the scope thereof is determined by the claims that follow.

1. A solar cell processing system, comprising:
a substrate automation system having one or more conveyors that are configured to transfer substrates serially through a processing region in a first direction, wherein the processing region is maintained at a pressure below atmospheric pressure;
a first processing chamber having two or more first deposition sources disposed in the processing region, wherein each first deposition source is configured to separately deliver a processing gas to a surface of each of the substrates as the substrates are transferred through the processing region relative to the two or more first deposition sources; and
a second processing chamber having two or more first deposition sources disposed in the processing region, wherein each second deposition source is configured to separately deliver a processing gas to the surface of each of the substrates as the substrates are transferred through the processing region relative to the two or more second deposition sources.

2. The solar cell processing system of claim 1, further comprising:
an actuator assembly that is configured to position substrates serially on a surface of one of the two or more conveyors.

3. The solar cell processing system of claim 1, further comprising:
a first substrate interface module disposed at a first end of the substrate automation system, and having an automation device configured to serially transfer substrates from a substrate carrier to the substrate automation system; and
a second substrate interface module disposed at a second end of the substrate automation system, and having an automation device configured to serially transfer substrates from the substrate automation system to a substrate carrier.

4. The solar cell processing system of claim 1, wherein the one or more conveyors comprises a first conveyor and a second conveyor, and the processing system further comprises:
a substrate reorientation device disposed in the processing region, and having an actuator that is configured to rotate substrates about an axis to reorient the substrates from a first orientation to a second orientation, wherein the substrate reorientation device is positioned to receive substrates disposed in the first orientation from the first conveyor and transfer the reoriented substrates to the second conveyor.

5. The solar cell processing system of claim 1, wherein the second deposition source surrounds the first deposition source.

6. The solar cell processing system of claim 5, wherein the first deposition source comprises:
a first outer shell;
a first electrode disposed in the first outer shell shaped to form a first cavity portion;
a first magnetic shunt coupled with the first electrode;
a first plate coupled with the first outer shell; and
a first magnet disposed adjacent the first plate and adjacent an end of the first cavity portion.

7. The solar cell processing system of claim 6, wherein the second deposition source comprises:
a second outer shell;
a second electrode disposed in the second outer shell shaped to form a second cavity portion;
a second magnetic shunt coupled with the second electrode;
a second plate coupled with the second outer shell; and
a second magnet disposed adjacent the second plate and adjacent an end of the second cavity portion.

8. The solar cell processing system of claim 1, further comprising a load lock chamber having a load lock region disposed therein, wherein the load lock chamber comprises:
a plurality of separation mechanisms coupled to a linear conveying mechanism disposed in the load lock chamber and positioned to divide the load lock region into a plurality of discrete regions; and
one or more actuators in fluid communication with the load lock region and configured to reduce the pressure in each of the plurality of discrete regions.

9. The solar cell processing system of claim 8, wherein the load lock chamber further comprises:
a first actuator configured to provide a pressure within a first discrete region of the plurality of discrete regions;
a second actuator configured to provide a pressure within a second discrete region of the plurality of discrete regions that is greater than the pressure within the first discrete region; and
a third actuator configured to provide a pressure within a third discrete region of the plurality of discrete regions that is greater than the pressure within the second discrete region.

10. A solar cell processing system, comprising:
a substrate automation system having two or more conveyors that are configured to transfer substrates through a processing region in a first direction, wherein the processing region is maintained at a pressure below atmospheric pressure;
two or more first deposition sources that are each disposed in the processing region, and disposed in a spaced apart relationship along the first direction and a distance from a first portion of one of the two or more conveyors, wherein each first deposition source is configured to separately deliver a first processing gas to the first portion of the conveyor as the substrates are transferred through the processing region relative to the two or more first deposition sources;
one or more first energy sources configured to deliver energy to a region formed between the first portion of the conveyor and one of the two or more first deposition sources; and
two or more second deposition sources that are each disposed in the processing region, and disposed in a spaced apart relationship along the first direction and a distance from a second portion of one of the two or more conveyors, wherein each second deposition source is configured to separately deliver a second processing gas to the second portion of the conveyor as the substrates are transferred through the processing region relative to the two or more second deposition sources.

11. The solar cell processing system of claim 10, further comprising:
an actuator assembly that is configured to position substrates serially on a surface of one of the two or more conveyors.

12. The solar cell processing system of claim 10, further comprising:
a first substrate interface module disposed at a first end of the substrate automation system, and having an automation device configured to serially transfer substrates from a substrate carrier to the substrate automation system; and
a second substrate interface module disposed at a second end of the substrate automation system, and having an automation device configured to serially transfer substrates from the substrate automation system to a substrate carrier.

13. The solar cell processing system of claim 10, wherein the two or more conveyors comprises a first conveyor and a second conveyor, and the processing system further comprises:
a substrate reorientation device disposed in the processing region, and having an actuator that is configured to rotate substrates about an axis to reorient the substrates from a first orientation to a second orientation, wherein the substrate reorientation device is positioned to receive substrates disposed in the first orientation from the first conveyor and transfer the reoriented substrates to the second conveyor.

14. The solar cell processing system of claim 10, further comprising: further comprising a load lock chamber having a load lock region disposed therein, wherein the load lock chamber comprises:
a plurality of separation mechanisms coupled to a linear conveying mechanism disposed in the load lock chamber and positioned to divide the load lock region into a plurality of discrete regions; and
one or more actuators in fluid communication with the load lock region and configured to reduce the pressure in each of the plurality of discrete regions.

15. The solar cell processing system of claim 14, wherein the load lock chamber further comprises:
a first actuator configured to provide a pressure within a first discrete region of the plurality of discrete regions;
a second actuator configured to provide a pressure within a second discrete region of the plurality of discrete regions that is greater than the pressure within the first discrete region; and
a third actuator configured to provide a pressure within a third discrete region of the plurality of discrete regions that is greater than the pressure within the second discrete region.

16. A method of forming a solar cell, comprising:
reducing the pressure in a processing region of a solar cell processing system to a pressure below atmospheric pressure;
positioning substrates on a substrate automation system that is at least partially disposed in the processing region, wherein the substrate automation system is configured to transfer substrates in a first direction through at least a portion of the processing region;
delivering a first processing gas from two or more first deposition sources that are each disposed in the processing region, wherein each of the two or more first deposition sources are configured to deliver the first processing gas to a deposition region formed between the first deposition source and at least one of the substrates positioned on the substrate automation system;
delivering a second processing gas from two or more second deposition sources that are each disposed in the processing region, wherein each of the two or more second deposition sources are configured to deliver the second processing gas to a deposition region formed between the second deposition source and at least one of the substrates positioned on the substrate automation system; and
forming a plasma in each of the deposition regions by delivering energy from one or more sources.

17. The method of claim 16, wherein positioning the substrates comprises serially transferring the substrates to a surface of the substrate automation system as the surface is translated in the first direction to form at least one row of substrates that extend along the first direction.

18. The method of claim 16, further comprising:
receiving substrates disposed in a first orientation from the first substrate automation system that comprises a first conveyor and a second conveyor, wherein receiving substrates comprises positioning at least one of the substrates on a substrate reorientation device that is disposed in the processing region;
rotating the at least one substrate about an axis to reorient the at least one substrate from the first orientation to a second orientation; and
transferring the rotated at least one substrate to the second conveyor.

19. The method of claim 16, further comprising:
transferring each substrate from atmospheric pressure to a first pressure region, wherein the first pressure region has a pressure that is less than atmospheric pressure;
transferring each substrate from the first pressure region to a second pressure region, wherein the second pressure region has a pressure that is less than the pressure in first pressure region;
transferring each substrate from the second pressure region to a third pressure region, wherein the third pressure region has a pressure that is less than the pressure in the second pressure region; and
transferring each substrate from the third pressure region to the processing region, wherein the processing region has a pressure that is less than the pressure in the third pressure region.

20. The method of claim 16, further comprising:
positioning substrates serially on a surface of the substrate automation system.

21. The method of claim 16, further comprising:
serially transferring substrates from a substrate carrier to the substrate automation system to a surface of the substrate automation system as the surface is translated in the first direction; and
serially transferring substrates from the substrate automation system to a substrate carrier as the surface is translated in the first direction.
